(19) United States
(12) Patent Application Publication
(10) Pub. No.: US 2011/0045656 A1
(43) Pub. Date: Feb. 24, 2011

(54) SYSTEM AND PROCESS FOR DICING INTEGRATED CIRCUITS

(75) Inventor: Chong Chen Lim, Singapore (SG)

Correspondence Address: HESLIN ROTHENBERG FARLEY & MESITI PC, 5 COLUMBIA CIRCLE, ALBANY, NY, 12203, US

(73) Assignee: ROKKO VENTURES PTE, LTD., Singapore (SG)

(21) Appl. No.: 12/937,509

(22) PCT Filed: May 30, 2008
(86) PCT No.: PCT/SG08/00200

§ 371 Date: Oct. 12, 2010

(30) Foreign Application Priority Data
Apr. 14, 2008 (SG) 200802888-8

(51) Int. Cl. H01L 21/304; B26D 7/01; B26D 7/27

(52) U.S. Cl. 438/462; 83/648; 83/168; 83/78; 257/E21.238

(57) ABSTRACT

An assembly for cutting a plurality of substrates into individual integrated circuit units includes a first block for receiving a first substrate. The first block is movable between a first loading position, a first alignment inspection station and a first cutting zone. A second block for receiving a second substrate is movable between a second loading position, a second alignment inspection station and a second cutting zone. A cutting device for cutting a substrate into individual integrated circuit units is movable between the first cutting zone and the second cutting zone. An alignment inspection device for determining the alignment of a substrate positioned on either the first or second block is movable between the first alignment inspection station and the second alignment inspection station.

### FIELD OF THE INVENTION

The invention relates to the process of integrated circuits and in particular, that part of process whereby the individual integrated circuit units are diced or singulated from a substrate containing many of said integrated circuits.

### BACKGROUND OF INVENTION

In determining the economic parameters for the design of a singulation device for cutting substrates into integrated circuit units, two of the key criteria are the rate at which units are processed, measured in units per hour (UPH) and the capital cost of the device for performing the action.

Traditional singulation devices provide for a linear path for the processing of a substrate from loading the substrate to cutting and then unloading which also includes intermediary steps such as checking alignment and cleaning of the singulated units.

To increase the UPH other devices incorporate parallel linear paths whereby two or more substrates are loaded simultaneously and undergo cutting and unloading together with alignment check and cleaning using multiple stations of the same functional device. For instance, in order to have two substrates processed simultaneously, two sets of dicing saws are required and so two separate cutting stations incorporated. Due to bottlenecks and other fixed delay in the process, the UPH of such a parallel system is not quite double the UPH of the single linear path machine mentioned previously. Nevertheless, the effect is a market increase in the UPH. However, the downside is the extra costs in providing multiple versions of each functional station. For instance, the extra cost of including a second cutting station to accommodate two parallel substrate paths is significant.

It would, therefore, be preferable if a system were available that provided a comparable UPH to the parallel system without the dramatic increase in capital costs.

### SUMMARY OF INVENTION

In a first aspect the invention provides an assembly for cutting a plurality of substrates into individual integrated circuit units comprising a first block for receiving a first substrate, said first block movable between a first loading position, a first alignment inspection station and a first cutting zone; a second block for receiving a second substrate, said second block movable between a second loading position, a second alignment inspection station and a second cutting zone; a cutting device for cutting a substrate into individual integrated circuit units, said cutting device movable between the first cutting zone and the second cutting zone, and; an alignment inspection device for determining the alignment of a substrate positioned on either the first or second block, said alignment inspection device movable between the first alignment inspection station and the second alignment inspection station.

In a second aspect the invention provides a method for cutting a plurality of substrates into individual integrated circuit units, the method comprising the steps of: placing a first substrate on a first block; moving said first block between a first loading position, a first alignment inspection station and a first cutting zone; placing a second substrate on a second block; moving said second block between a second loading position, a second alignment inspection station and a second cutting zone; moving a cutting device between the first cutting zone and the second cutting zone for cutting a substrate, and cutting the first or second substrate into integrated circuit units when located in said zone; respective first or second moving an alignment inspection device between the first alignment inspection station and the second alignment inspection station and determining the alignment of the first or second substrate when located in said respective alignment station.

The following description of the invention and its various embodiments will use interchangeable language in describing the various parts. For instance, a block for receiving substrate may include a chuck table or other similar device. The cutting process defined by the invention may involve dicing saws and so the terms cutting, sawing and dicing may be used interchangeably when considering linear cutting of said substrates. The present invention may also include other cutting techniques, including laser cutting and water jet.

Where systems of the prior art rely on purely linear process steps or alternatively parallel paths which individually are linear, the present invention provides for overlapping processes which may rely on singular capital equipment rather than provide multiple duplicates of said equipment whilst still maintaining a UPH of a comparable level.

In a further embodiment, the assembly may further include a cleaning station to which the first and second blocks may move. For instance, on completion of the cutting stage, the block may move to a cleaning station whereby the surface of the substrate exposed during cutting of the units undergoes cleaning Said cleaning may include subjecting the units to air and water jets. In conventional systems, cleaning of the integrated circuit units after cutting is done by the cutting device which uses liquid, often water, to assist in the cutting. Thus, after the cutting process, the water associated with the saws are used to then clean the integrated circuit units. This, of course, leads to the cutting cycle lasting beyond the cutting stage and extending to cleaning. By providing a cleaning station separate from the cutting station following the cutting action, the cutting saws may then move to the next block and commence cutting immediately. As the cutting cycle may be the longest period in the process, by reducing the cutting cycle through removal of the cleaning phase may reduce the bottleneck in the cutting cycle and so increase the UPH of the overall assembly.

On return of the blocks to their original position and following removal of the integrated circuit units from the block, each block may be cleaned again. This action is often referred to as “jig cleaning”. Again in conventional systems, jig cleaning occurs through returning the block to the cutting station for further cleaning by the water jets associated with the cutting saws. As the cutting saws are occupied by this jig cleaning phase, they are unavailable for further cutting action and so, reducing the UPH of the device. By incorporating a discreet cleaning station separate from the cutting saws in accordance with this embodiment of the present invention, the cutting saws are not occupied during jig cleaning and so, may continue cutting of a substrate on a second block.

In a further embodiment, the assembly may include a third block for receiving a third substrate, said third block movable between a third loading position, a third alignment inspection and a third cutting zone. In this case, the cutting device may also be movable to the third cutting zone, and the alignment inspection device movable to the third alignment inspection. In this way, the capacity of each station may be further maximized, or alternatively, the UPH increased.

It will be clear to the skilled person that further blocks may be added, with the sequence of delivering substrates including each block. The process may therefore be further staggered to accommodate each additional block.

In a still further embodiment, there may be several blocks, each having a substrate placed thereto, and each movable to cutting and inspection zones. To assist in the UPH and/or to prevent bottlenecks in the process, an additional cutting device may be incorporated. Thus, for several such blocks, there may be an optimum number of cutting devices to meet the requirements of the designer.

Still further, there may further be additional inspection devices, again to accommodate several blocks and cutting devices.

Thus, for a known rate of cutting and alignment inspection, to achieve a desired UPH, it may be possible to calculate the optimum number of cutting devices and alignment inspection devices to meet this criterion. As these functional devices within the overall assembly number less than the number of blocks, such an embodiment of the present invention is distinct from the parallel system of the prior art, whereby each block corresponded to a cutting device and alignment inspection device. Further, it may yield a considerably higher UPH than that of a single substrate device, and so provide distinct advantage over such systems.

For illustrative purposes only, an extreme embodiment of such a system may incorporate five blocks operating with three cutting devices and two alignment inspection devices. Whilst this extreme example may involve operational difficulties, it demonstrates the breadth for which the present invention may be extended in order to provide significant benefit over the prior art.

In a third aspect, the invention provides an assembly for cutting a plurality of substrates into individual integrated circuit units comprising a first block for receiving a first substrate, said first block movable between a first loading position and a first cutting zone; a second block for receiving a second substrate, said second block movable between a second loading position and a second cutting zone; a cutting device for cutting a substrate into individual integrated circuit units, said cutting device movable between the first cutting zone and the second cutting zone.

In a fourth aspect, the invention provides a method for cutting a plurality of substrates into individual integrated circuit units, the method comprising the steps of: placing a first substrate on a first block; moving said first block between a first loading position and a first cutting zone; placing a second substrate on a second block; moving said second block between a second loading position and a second cutting zone; moving a cutting device between the first cutting zone and the second cutting zone for cutting a substrate, and cutting the first or second substrate into individual integrated circuit units when located in said zone.

In a fifth aspect, the invention provides a sorting system for sorting integrated circuit units comprising a dry block for receiving the units from a bulk unit picker; a first net table for receiving a first batch of said units, said first net table movable between a first receiving position and a first sorting position; a second net table for receiving a second batch of units, said second net table movable between a second receiving position and a second sorting position, and; a second bulk unit picker for delivering said respective first and second batch of units from the dry block an idle block, and subsequently from the idle block to the first and second net tables whilst in respective first and second receiving positions.

In a sixth aspect, the invention provides a unit inversion system comprising a dry block for receiving a plurality of units; a flipper for receiving the plurality of units from the dry block and inverting said units; a net table for receiving the units from the flipper; wherein said net table includes two surfaces, the surfaces arranged to receive respective first and second batches of units in a predetermined orientation.

In a seventh aspect, the invention provides a conversion kit assembly for receiving integrated circuit units comprising an engagement member, having engagement portions in an engagement face of said engagement member, each portion arranged to receive a single unit; a first manifold element having a first duct network, said first manifold element engageable with a first vacuum source; a second manifold element having a second duct network, said second manifold element engageable with a second vacuum source; wherein on assembling the engagement member, first manifold element and second manifold element, said first vacuum source is in vacuum communication with a first plurality of engagement portions and the second vacuum source is in communication with a second plurality of engagement portions, the first and second plurality of engagement portions forming respective pre-determined arrangement.

In an eighth aspect, the invention provides A picker assembly for engaging integrated circuit units comprising an engagement member, having a plurality of engagement fingers projecting from an engagement face of said engagement member, each engagement fingers arranged to engage a single unit; said engagement fingers arranged to extend away from the engagement face on activation of a vacuum source applied to said engagement finger and retract on deactivation of said vacuum source; a first manifold element having a first duct network, said first manifold element engageable with a first vacuum source; a second manifold element having a second duct network, said second manifold element engageable with a second vacuum source; wherein on assembling the engagement member, first manifold element and second manifold element, said first vacuum source is in vacuum communication with a first plurality of engagement fingers and the second vacuum source is in communication with a second plurality of engagement fingers, the first and second plurality of engagement fingers forming respective pre-determined arrangement.

### BRIEF DESCRIPTION OF DRAWINGS

It will be convenient to further describe the present invention with respect to the accompanying drawings that illustrate possible arrangements of the invention. Other arrangements of the invention are possible and consequently the particularity of the accompanying drawings is not to be understood as superseding the generality of the preceding description of the invention.

FIG. 1 is a plan view of a system according to one embodiment of the present invention;

FIG. 2 is a plan view of a system according to a further embodiment of the present invention;

FIGS. 3A, 3B and 3C are various views of a chuck table arrangement according to a further embodiment of the present invention;

FIG. 4 is an elevation view of the dicing and sorting sections of a system according to a future embodiment of the present invention;

FIGS. 5A and 5B are sequential steps in a cleaning process according to a further embodiment of the present invention;

FIGS. 6A, 6B and 6C are various views of a sorting system according to a further embodiment of the present invention;

FIG. 7A is an elevation view of a unit inversion system according to one embodiment of the present invention;

FIG. 7B is an elevation view of a unit inversion system according to a further embodiment of the present invention;

FIG. 7C is an elevation view of a unit inversion system according to a further embodiment of the present invention;

FIG. 7D is an elevation view of a unit inversion system according to a further embodiment of the present invention;

FIG. 8A is a plan view of the unit inversion system of FIG. 7A;

FIG. 8B is a plan view of the unit inversion system of FIG. 7B;

FIG. 8C is a plan view of the unit inversion system of FIG. 7C;

FIG. 8D is a plan view of the unit inversion system of FIG. 7D;

FIGS. 9A to 9D are various views of an unloading assembly according to an embodiment of the present invention, and;

FIGS. 10A and 10B are elevation views of an unloading assembly according to a further embodiment of the present invention.

FIGS. 11A to 11E are various views of a conversion kit assembly of the prior art;

FIGS. 12A to 12G are various views of a conversion kit assembly according to one embodiment of the present invention and;

FIGS. 13A and 13B are various views of a conversion kit assembly for a picker according to a further embodiment of the present invention.

### DESCRIPTION OF THE PREFERRED EMBODIMENT

The invention relates to a means of increasing the rate of units per hour (UPH) without a marked increase in capital equipment. In affecting a device that meets the present invention, it is likely that additional equipment is required to maneuver substrates to the required position. Further, in order to duplicate the function of individual devices within the overall system, these may also need to move and, therefore, control systems and linear rails may increase the costs of the device over a simple single substrate system. Nevertheless, it is further likely that embodiments of the present invention may have reduced capital costs because of the increase usage of devices such as cutting saws and so, not requiring multiple versions of the same functional device. Thus, in one embodiment the present invention provides for processing multiple substrates at approximately the same time, with the stages of the process for each substrate staggered so as to better utilize the available equipment. Whilst the first substrate undergoes alignment checking and then cutting, a second substrate can be loaded and prepared for the dicing stage. Thus, the invention provides the advantage of reducing the cost of duplicate devices within the system such as multiple dicing saws whilst maintaining a UPH which is greater than that of a single substrate system, and may be comparable with the UPH of a parallel system through better utilization of the available equipment.

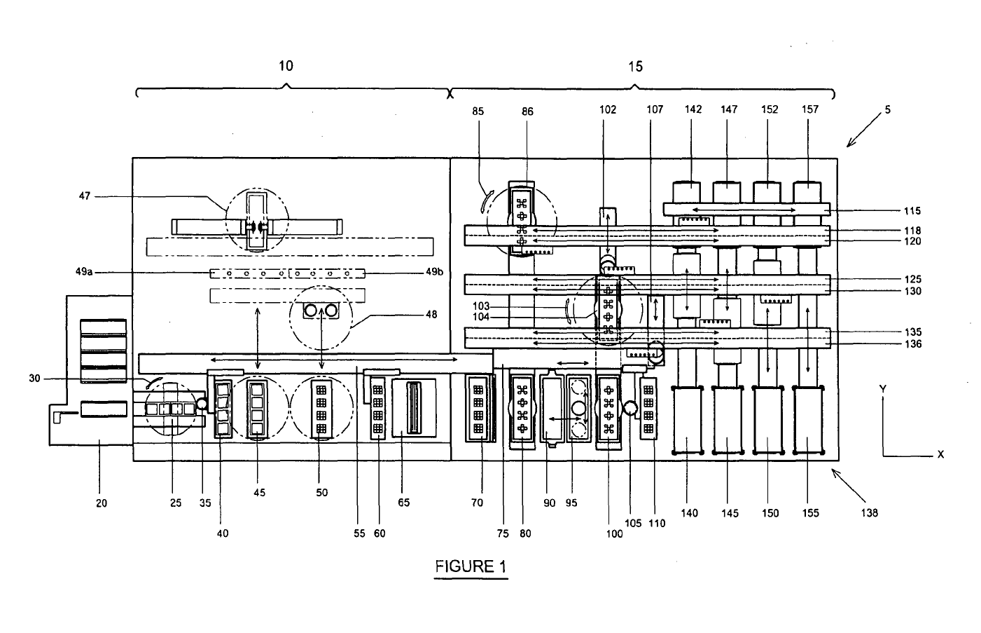

FIG. 1 shows a device 5 arranged to provide these advantages. The device 5 is divided into two separate sections being the dicing section 10 and the sorting section 15. At one end, a loading station 20 loads substrates to a frame turntable 25 which reorients the substrate from the loading position to the dicing position. The substrate is engaged by a frame picker 40, having a camera 35 attached thereto. The camera checks the position of the substrate on the table 25 to ensure it is correctly aligned prior to being engaged by the frame picker 40. The frame picker 40 delivers the substrate to one of two blocks arranged to receive the substrates, in this case, chuck tables 45, 50 depending upon the stage in the process. The chuck tables are located at a first loading position, which for the subsequent description will be defined as the “original position”.

Also within the dicing section 10 is a cutting saw 47 and an alignment inspection device 48, both of which are mounted to linear slides for selectively sliding between two zones. Further located within the cutting section 10 is a cleaning station 49a,b

Each of the chuck tables 45, 50, are arranged to move upon linear slides so as to coincide with each of the cutting saw cleaning station and alignment inspection device. The cutting saw 47 can only accommodate one substrate at a time and, therefore, must slide from a first cutting zone which coincides with a point upon the rail, servicing the first chuck table and a second cutting zone coinciding with a point on the rail of the second chuck table. Accordingly the cutting saw 47 slides backward and forth between the two cutting zones depending upon which chuck table it is servicing at that time. Similarly the alignment inspection device 48 moves from a first alignment inspection station to a second alignment inspection station corresponding to the first and second chuck tables. Accordingly, the alignment inspection 48 will slide back and forth between the alignment inspection stations depending upon which chuck table it is servicing.

The cleaning station 49a,b in this embodiment are fixed in place and therefore, the cleaning station associated with the first chuck table has a cleaning portion 49a for that chuck table and a second portion 49b for the second chuck table. It will be appreciated that other embodiments of the present invention may have a single cleaning portion located upon a linear slide similar to the cutting saw and alignment inspection device whereby cleaning is also moved selectively.

Each chuck table 45, 50 is arranged to deliver the substrate to inspection station 48 before them passing to a cutting station 47 and then to a cleaning station 49a,b. Because the substrates are delivered one at a time, the processing of any one substrate is staggered in relation to the next substrate.

In one embodiment of the process, during the alignment inspection 48 stage, or alternatively, during the cutting phase 47, a second substrate is loaded to the second chuck table 50. On completion of the cutting stage of the first substrate, the first substrate is then moved to the cleaning station 49a whereby material collecting on the surface cut by the cutting saw is washed away. The cleaning station 49a subjects the surface of the cut substrate with jets of air and water so as to remove the particulate matter. Once the first substrate is clear of the cutting station, the second substrate may be delivered to the second cutting zone, to coincide with the cutting saw 47, which slides from the first cutting zone. The substrates follow the path through the system staggered from each other by a period set to meet the objectives of the designer.

To aid in the cutting process, liquid, often water is provided as a means of aiding the cutting, acting as both a lubricant and a coolant to maintain temperature within the cutting zone. Systems of the prior art use this water supply as a means of cleaning the substrate after the cutting process and further, when the individual integrated circuit units are removed from the block, the block is then returned to the cutting saw to clean the block (known as “jig cleaning”). The actual time taken to cut the substrate is a significant time period in the overall process. With convention systems using water from the cutting surface to both clean the integrated circuits and also to later clean the block, extends the time for which the cutting source are unavailable to cut another substrate.

The advantage of providing a cleaning station 49a, 49b is to first clean the substrate and so free the cutting saw from this activity and later, when the integrated circuit units are removed from the block, the same cleaning station 49a, b can be used for jig cleaning again, without interfering with the normal function of the cutting saw. Accordingly, the availability of the cutting saw to actually cut substrates is significantly increased by removing the unrelated cleaning task from the device.

One objective may be to minimize the down time of any one or several stations within the device. Another objective may be to limit the bottleneck experienced at any particular stage. In this case, emphasis may be placed upon maximizing UPH rather than maximizing the usage of any particular stage.

As with similar processes, a substrate may follow the process of:
i) Loading (40)
ii) checking of alignment (48)
iii) cutting (47)
iv) cleaning of diced units (49a, b)
v) unloading (60)
vi) cleaning of jig (49a, b)

A key feature of the invention is the ability to run two substrates in parallel but having a staggered commencement such that any or all of the stations of the device 5 are at an optimum capacity or alternatively to operate the device so as to maximize UPH and so avoid bottlenecks at critical points within the process. For instance, of the above mentioned process steps, cutting may be of the greatest duration and so loading of the second substrate to the second chuck table 50 may be delayed until cutting of the first substrate is imminent or has commenced. The second substrate can then undergo loading and alignment so as to be ready for cutting on completion, or have a short delay prior to the cutting station being made available.

In this embodiment, the movement of the substrates on the chuck tables 45, 50 is achieved by moving the various stations 47, 48 to the chuck tables themselves. That is, the first and second chuck tables 45, 50 operate along rails or other means to move the substrate to designated alignment inspection stations 48 and cutting stations 47.

The device further includes a bulk unit picker 60 moving along a common rail with the frame picker 40 to collectively engage the singulated integrated circuit units from both the first and second chuck tables 45, 50. The units are passed through a cleaning box 65 and deposited on a dry block 70.

The units are then passed through a flipper 90 and edge block, 95 before being delivered to a first net block 80 or a second net block 100 in an inverted orientation. From here, the singulated units follow a parallel path whereby the first net block is delivered to a pair of twin rails 118, 120, 125 upon which unit pickers operate to deposit individual units into the various categories identified by trays 142, 152. Similarly the second net block 100 may be positioned so as to engage a second set of twin rails 130, 135, 136 having corresponding unit pickers for again picking up individual units for deposit to the category trace 147, 152.

Accordingly the trays each have discreet rails upon which they can collect individual units from the two sets of parallel rails for eventual depositing to end bins 140, 145, 150. Here, “good” units may be deposited into two bins 140, 145 with “rework” units deposited to a third bin 150 and “reject” units deposited to a final bin (not shown) for disposal.

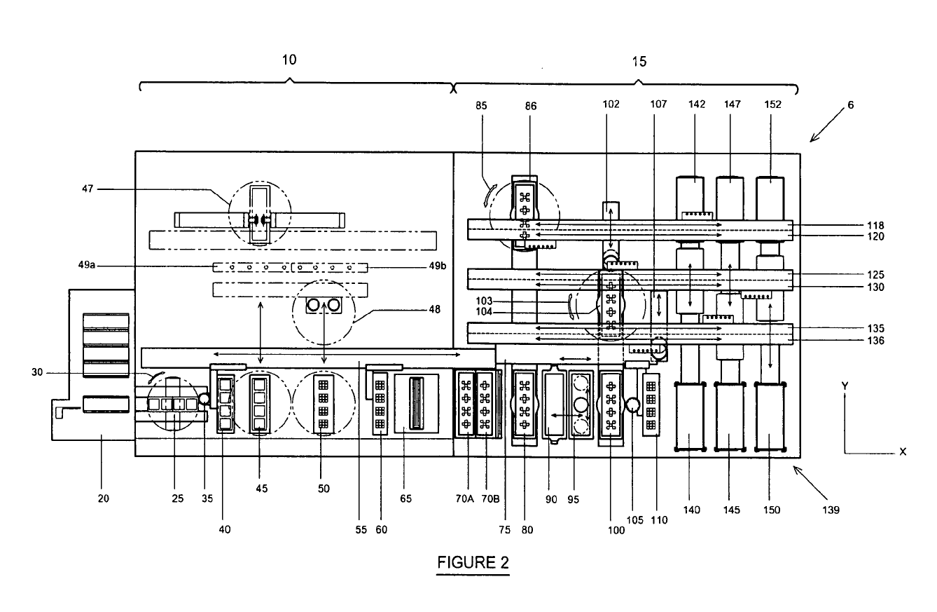

FIG. 2 shows an alternative plan of the device 6 according to a further embodiment of the present invention. This embodiment may be advantageous small units below 4×4 to 0.5×0.5, given the added clearance about the units for the various unit pickers, as will be described in more detail below.

The difference lies in the dry block. In the embodiment of FIG. 1, a single dry block 70 receives all of the integrated circuit units from the bulk unit picker 60. In FIG. 2, two dry blocks 70a,b are provided with the units divided between the two. This division facilitates the split of units between the two net tables 80, 100 rather than collecting from a single supply of units as in the embodiment FIG. 1.

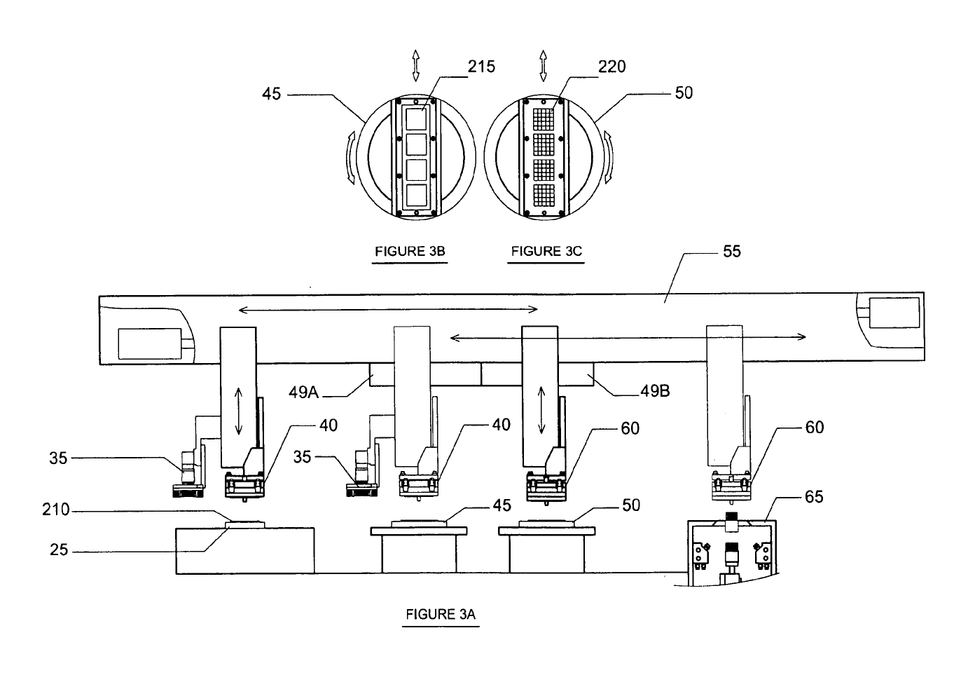

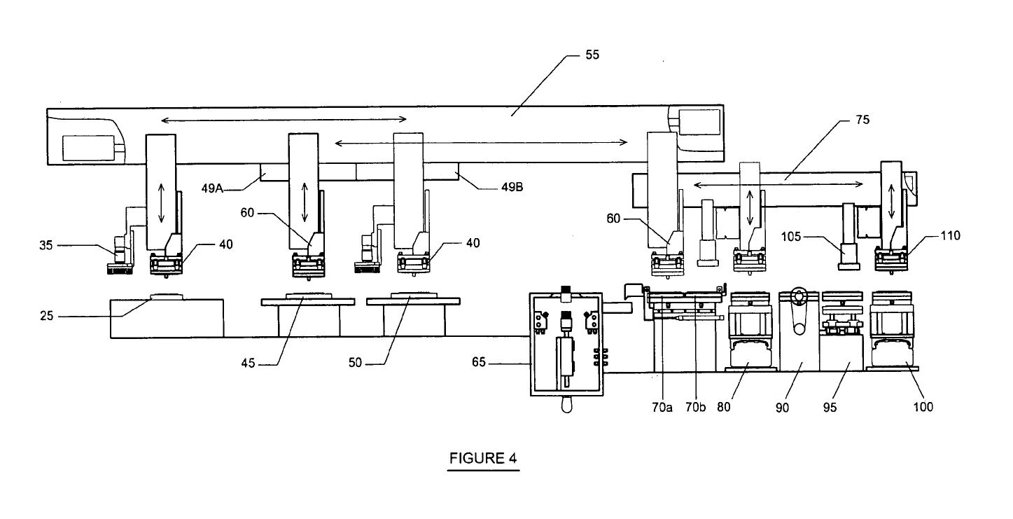

The foregoing has described a device according to one embodiment of the present invention. FIGS. 3 to 10 further describe various features of the device and will be described in more detail. It will be appreciated that the device described herein is merely one embodiment of the present invention with other arrangements possible.

FIG. 3A shows an elevation of the chuck table arrangement whereby the substrates are received and placed within the cutting section and then removed so as to be cleaned by the cleaning block 65.

After loading the substrate 210 to the turntable 25, the substrate is rotated so as to be in the correct alignment for the cutting section later in the process. A frame picker 40 moving along a linear rail 55 can move proximate to the turntable 25 so as to inspect the substrate 210 using a camera 35. Once the parameters have been identified, the frame picker 40 engages the substrate using a vacuum source and places the substrate on to either the first chuck table 45 or the second chuck table 50 depending on which chuck table is available. As the devices processes the substrates sequential, the frame picker 40 will alternate between placing a substrate on the first 45 then second chuck table 50.

If the substrate 210 is the first to be processed, it will be delivered to the first chuck table 45 and if the second to the second chuck table 50. It is this alternating placement which permits the staggered processing of the substrates relative to the previous and subsequent substrates. The timing of the chuck tables 45, 50 can then be arranged so as to precisely place the timing of the substrate entering the cutting section. Alternatively, the timing of the substrate within the process may be a function of the loading assembly 20 or further still, by the frame picker 40, selecting the time for which the substrate is transferred from the turntable 25 to the chuck tables 45, 50.

The chuck tables 45, 50 themselves are shown in FIGS. 3B and 3C. The tables are rotatable so that better access for the cutting saws within the cutting zone 47, and so both x and y oriented cuts are effected. Rotation can also facilitate inspection 48 by the device.

The process involves the placement of a substrate on the first chuck table 45 which then is transported to the alignment inspection 48 prior to cutting 47. The chuck table 45 is rotatable so as to permit access to any point on the substrate of both the alignment camera 48 and the cutting source 47 so as to fully process the substrate. The first chuck table 45 then moves to the cleaning station 49a whereupon the cut substrate is cleaned through subjecting the top phase to water and air jets so as to remove particulate matter formed from cutting of the substrate. The first chuck table then returns to its original position. After commencement of the processing of the first substrate, a second substrate is placed on the second chuck table 50 and delivered to the alignment camera 48, the cutting source 47 and finally to the corresponding cleaning station 49b. As noted, the alignment camera 48 and the cutting source 47 are located upon parallel rails so as to change their position subject to whether they are processing the first or second chuck tables 45, 50. The cleaning station however is fixed, having a first portion 49a corresponding to the first chuck table 45 and a second portion 49b corresponding to the second chuck table 50.

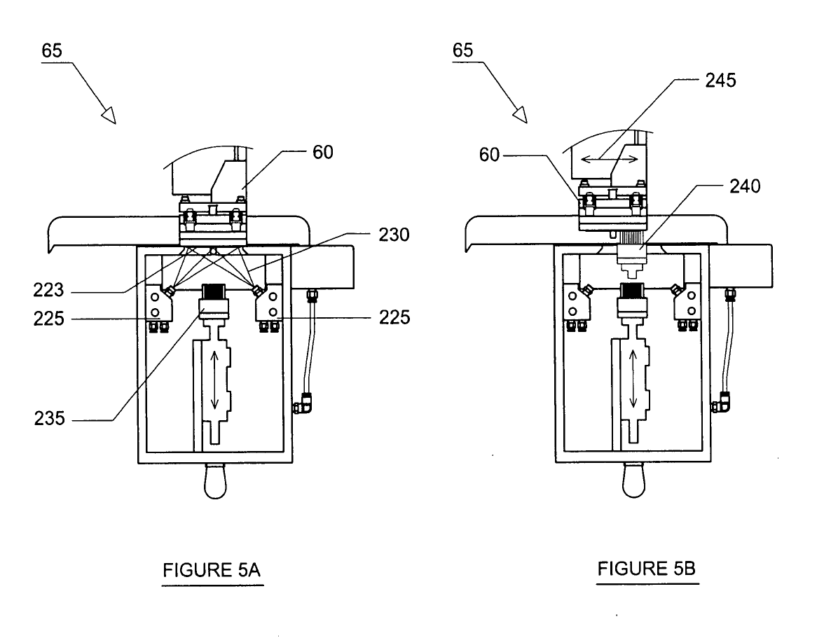

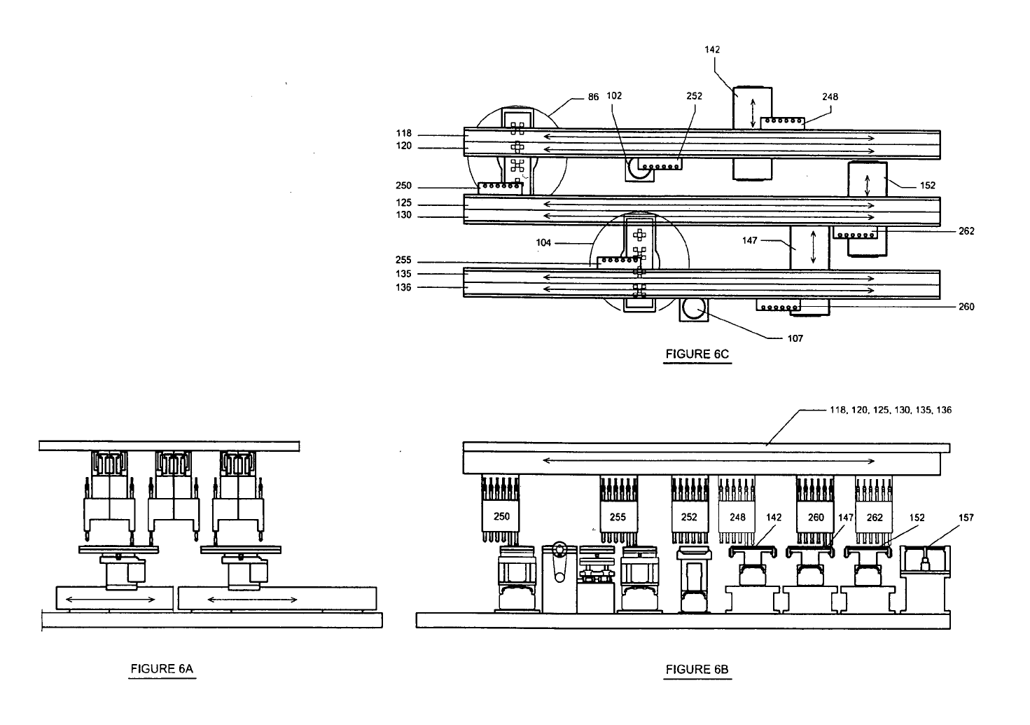

On return of the chuck tables 45, 50 to the original position, the singulated integrated circuit units are then engaged by a bulk unit picker 60, travelling along the same linear rail 55 as that of the frame picker 40. The bulk unit picker 60 is arranged to engage the units, as a batch from either chuck table 45, 50 and deliver these to the cleaning box 65. Whereas the cleaning stations 49a, b have cleaned one surface of the integrated circuit units, the cleaning box 65 is able to clean the opposed surface as the integrated circuit units are now engaged to the unit picker and so the underside becomes accessible by a cleaning device. Further details of the method of cleaning can be seen in FIGS. 5A and 5B.

The integrated circuit units are then delivered to a dry block 70 as shown in FIG. 4, prior to delivery to the flipper 90 and edge block 95. The means of delivery of the integrated circuit units involve a second unit picker 110 which moves along a second linear rail 75. In a further embodiment, the second unit picker may also travel along the first linear rail 55 in the case of the linear rail 55 extending in length so as to access the net tables 80, 100. However, in this embodiment the first linear rail 55 ends at the dry block 70 being the furthest extent of the bulk unit picker 60. Movement of the singulated integrated circuits is then subject to the second unit picker 110 for delivery of the integrated circuit units from the dry block to the flipper 90 and subsequently to either the first net block table 80 or the second net block table 100. As with the delivery of the substrates to the first and second chuck tables 45, 50, the second unit picker 110 delivers the units to the net tables in an alternating fashion.

With reference to the cleaning box 65, FIGS. 5A and 5B show the process by which the singulated integrated circuit units are cleaned prior to delivery to the dry block 70. Firstly, the bulk unit picker 60 lowers the units to the cleaning box 65 whereby nozzle 225 subject the units 223 to air jets 230 so as to dislodge any particulate matter from the units. In this orientation, a brush 235 is in a retracted position so as not to interfere with the air jets 230. After a designated period, the air jets stop and the brush 235 moves to an extended position 240 so as to contact the units 223. The bulk unit picker 60 then moves in a reciprocal motion 245 across the brush so as to perform a final removal of any particulate matter from the integrated circuits. On completion of this brushing motion, the units are then delivered to the dry block 70.

The first and second net tables 80, 100 are each located on linear slides so as to bring the tables in proximity to pairs of parallel rails having individual net pickers located thereon. FIGS. 6A, 6B and 6C show the arrangement by which the pickers 248, 250, 252, 255, 260, 262 engage the units from the respective net tables 86, 104 for delivery to trays 142, 147, 152 via the linear rails 118, 120, 125, 130, 135, 136.

Taking for instance the arrangement for the first net block 80, this is delivered to the first pair of rails 118, 120, 125 so as to permit access to the unit pickers 248, 250, 252. The first net table 86 is rotatable 85 so as to facilitate access of each unit to the unit pickers 248, 250, 252. It will be noted particularly in FIG. 6C that the placement of the integrated circuit units on the two net tables 86, 104 are in a “chequer board” arrangement. The unit picker 110 is arranged to lift the units from the dry block 70 and place half on the first net table 80 and the other half on the second net table 100. It follows that this is the arrangement of the units from which the individual unit pickers 248, 250, 252, 255, 260, 262 will engage the units and deliver them to the respective trays.

When each unit picker 248, 250, 252 is full, the units are transported to the corresponding tray 142 via a further inspection station 102 to perform a final inspection before delivering the units to the “good” tray 142 corresponding to this pair of rails 118, 120, 125. It will be noted that each pair of rails has a single “good” tray associated thereto. For instance, 142 corresponds to the rails for the first net block 86 and the second “good” tray 147 correspond to the rails for the second net block 104. Because of the smaller percentage of units falling into this category, a single “rework” tray 152 is operable between the two pairs of rails so that any “rework” units for either net table 86, 104 are delivered to the “rework” tray 152.

It will be noted that alternatives such as a single larger good tray operable between the two pairs may be incorporated. Similarly, the “rework” tray 152 may be replaced by a single “reject” bin where reworking of the integrated circuits is not practical or cost effective.

Further, a single pair of rails may be operable whereby the two net tables 86, 104 alternate in delivery of the units to the single pair of rails so as to reduce the equipment within the device 5. Further still, rather than two pairs of rails, two single rails each having two unit pickers movable upon it may replace the two pairs whereby movement of the unit pickers is arranged so as not to interfere with each other. For instance said unit pickers may be located on either side of the rail and so having a dual connection to the pickers or other such means as will be clear to the skilled person.

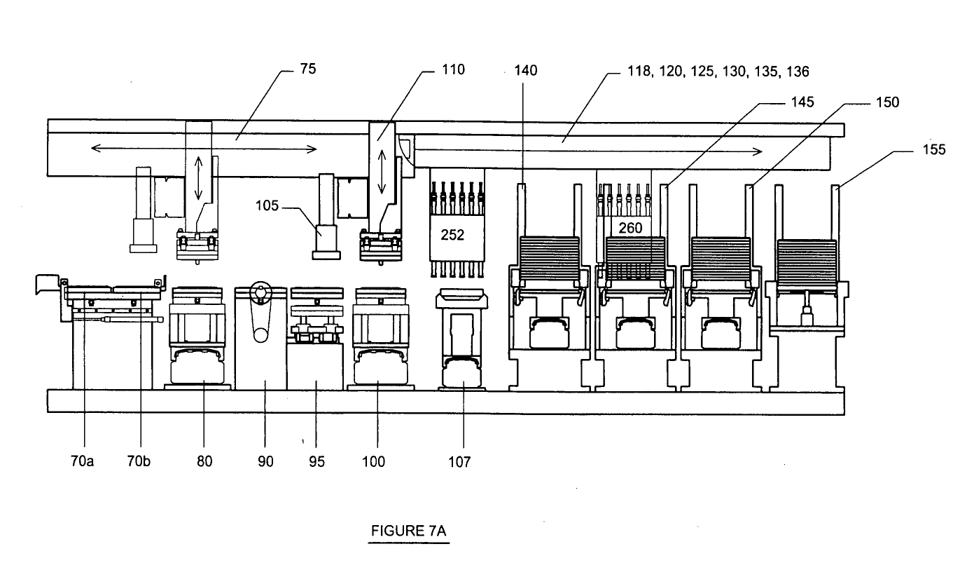

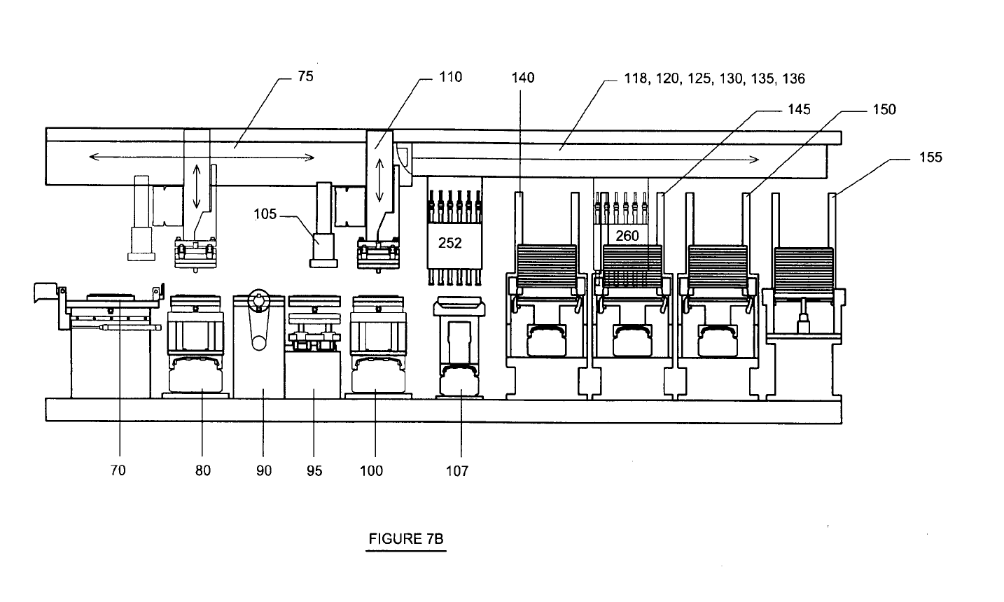

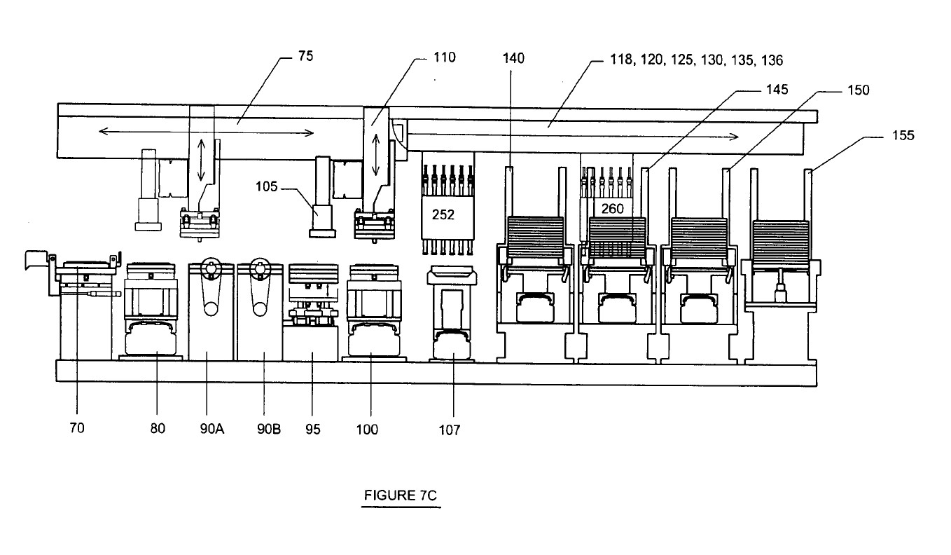

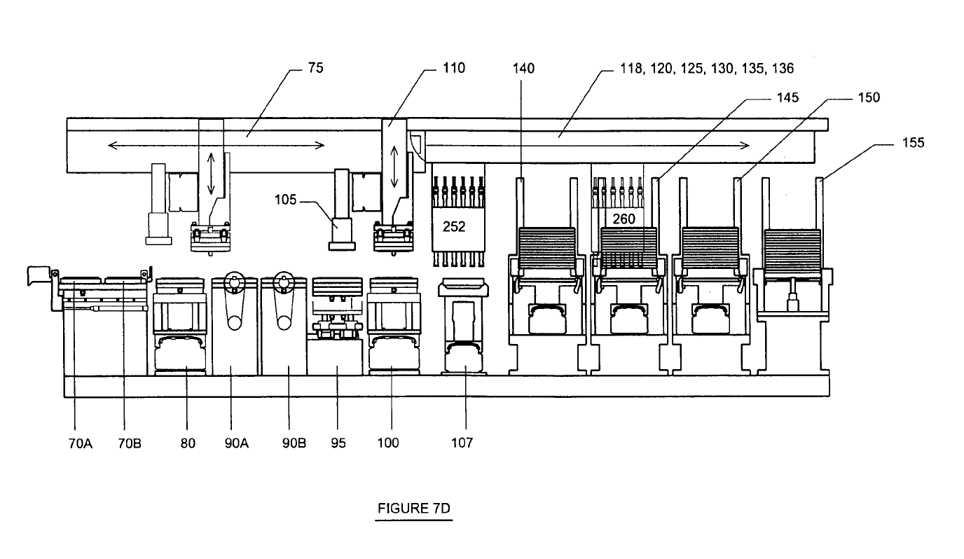

FIG. 7 shows a detailed view of the position of the net tables 80, and the end bins 140, 145, 150 into which each of the units are placed from the trays 142, 147, 152.

In this embodiment, the “good” units from the trays 142, 147 are respectively delivered to “good” bins 140, 145. It follows that the “rework” units are delivered to the “rework” bin 150 and similarly the “reject” units sent to the bin (not shown).

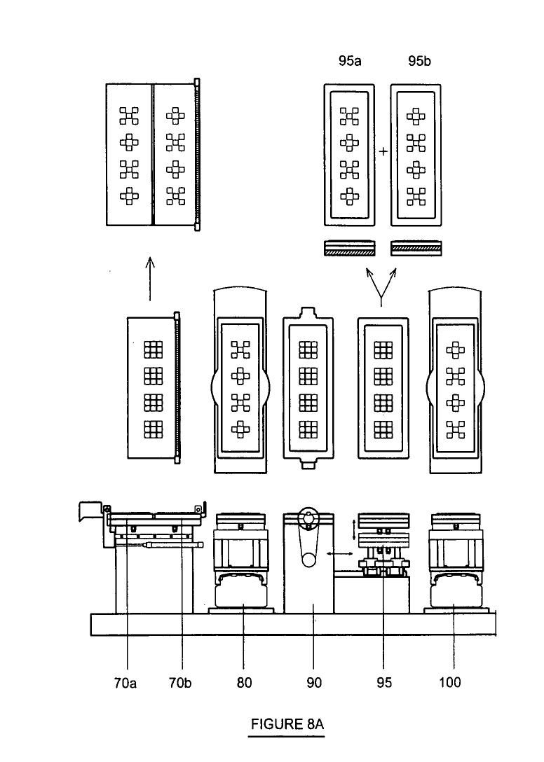

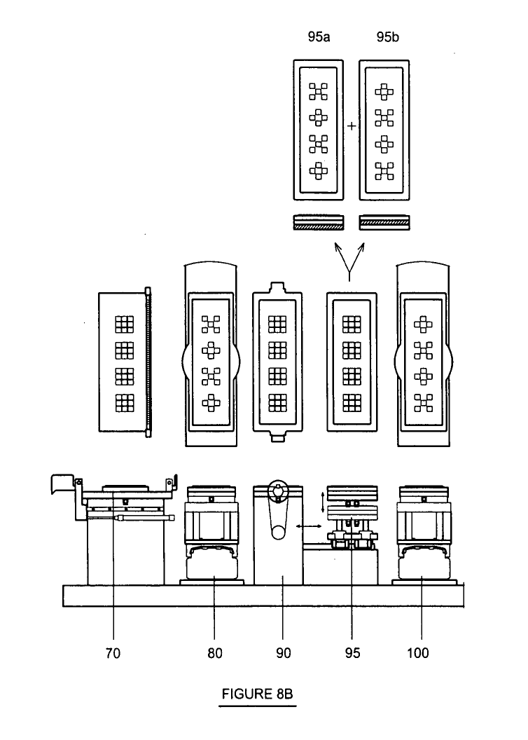

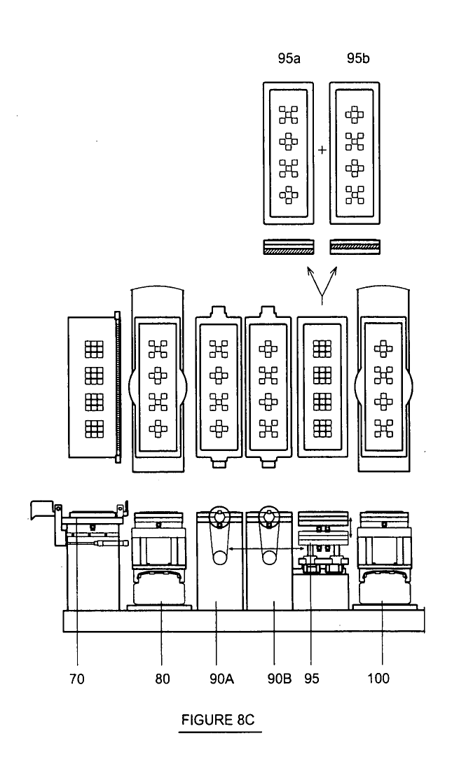

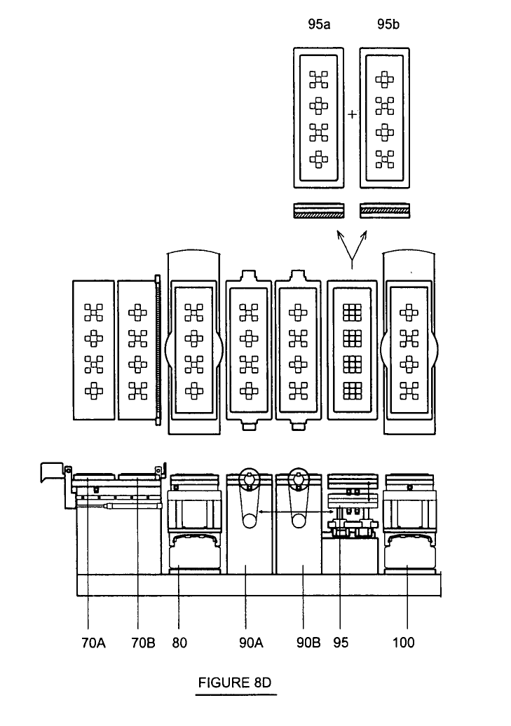

FIGS. 7A to 7D and FIGS. 8A to 8D describe various embodiments of the intermediate stage in the process between the dicing system and the sorting system. For the purposes of defining this intermediate stage, it will be referred to as a unit inversion system having distinct stations within it. These stations are variously referred to, in these embodiments, as the dry block 70 from which units are received from the dicing system, the flipper 90 for receiving the units from the dry block and inverting the units, the idle block 95 for receiving the units from the flipper 90 in the inverted form and the net table 80, 100 for temporarily holding the units whilst conducting the marking vision check. From the net tables the units are transported to the sorting system which will be subsequently described.

In addition to the above stations, FIGS. 7A to 7D show one of the unit inspection stations 102 providing a camera so as to view the units engaged by the unit picker 252, whilst within the unit inversion system.

The unit inversion system of FIG. 7A and show one arrangement for the dry block 70 and the idle block 95. In the embodiment shown in FIG. 1, the dry block receives all of the integrated circuit units in the same array orientation as they are singulated from the substrate. In the arrangement shown in FIG. 8A, the dry block 70 includes a pair of dry block surfaces 70a,b. Instead of the units being placed on the dry block by the bulk unit picker 60 in the same orientation, the units are instead divided between the two dry block surfaces 70a,b in a chequer board arrangement. In this way, access to small units, individually, is provided with greater clearance around the unit and so facilitates better management of the unit during transportation. FIG. 8A further shows an idle block 95 having a first and second surface 95a,b. The arrangement in 8A shows the idle block 95 as a single block receiving the units in the same orientation as that delivered to the dry block 70. In this embodiment, the idle block is divided into two surfaces each having discrete vacuum lines 95a,b such that first and second batches of units may be picked up by 2^{nd} Package Picker 110 to enhance placement on first net table 80. For clarity, the first and second batches of units arranged in the chequer board orientation will be designated P1 and P2 arrangements such that both are chequer board patterns but in opposed orientation having being divided from a uniform array of units as originally diced from the substrate. The first and second batches of units, placed in the chequer board arrangement on the idle block surfaces 95a, b will be picked up by the 2^{nd} Package Picker 110 to move to first net table 86 followed by the second batch of units, which is again picked up by 2^{nd} package picker 110 to move 2^{nd} net table 104. An arrangement according to the prior art involves the 2^{nd} Package Picker 110 picking up a full substrate of units (or packages) from idle block 95 then move to single net table to place a 1^{st} half of packages in the chequer board arrangement. During this action, the 2^{nd} half of packages which are held by the 2^{nd} unit picker 110 prevent the 1^{st} half of packages from reaching the net table surface, which need to be release from the net table surface. The present invention is to bring 1^{st} half of packages into net table pocket to make sure that 1^{st} half packages have enough contact with net table pocket, in order to make this process 2^{nd} Package picker have to pick up 1^{st} half packages from idle block 95a that remain 95b should hold by separate vacuum by idle block.

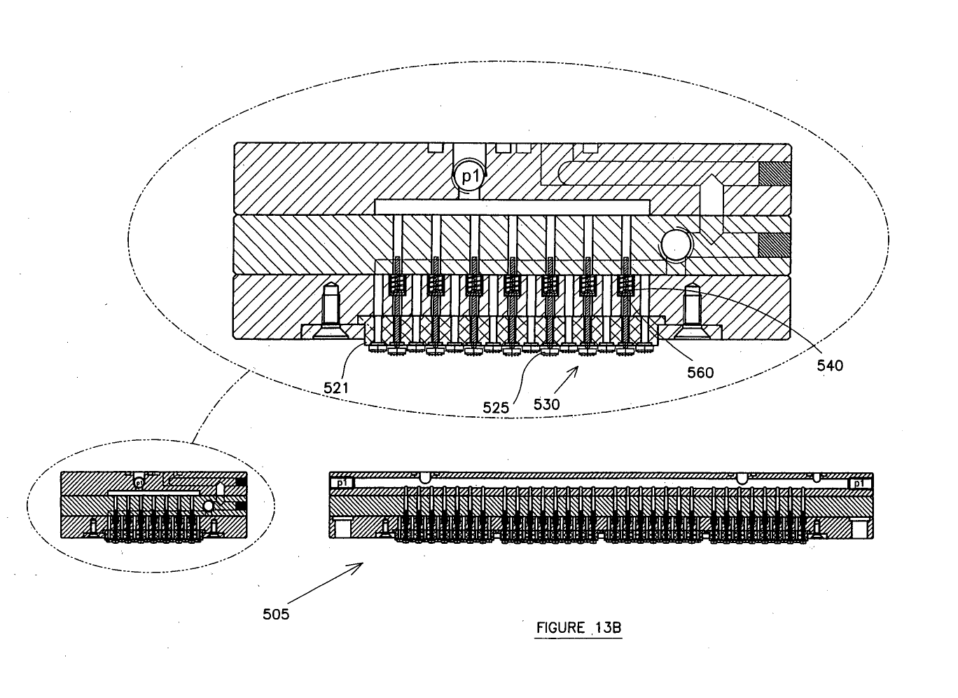

FIGS. 7B and 8B show an alternative arrangement to that shown in FIGS. 7A and 8A. In this orientation, there is only one dry block 70 from which the units are taken and so, the units are not divided into the P1 and P2 arrangement at this point. The units are then delivered to the stacked idle block surfaces 95a,b in respective P1 and P2 arrangements. The means by which the units are divided may vary and include the use of the second picker 110 selectively engaging units in a P1 orientation and delivering these to the first surface 95a, followed by the picker 110 engaging the remaining units in the P2 arrangement and delivering these to the second surface of the idle block 95b. By way of example, the picker assembly shown in FIGS. 13A and 13B describes one means of achieving this. The invention, however, is not restricted to the use of such an assembly and any assembly that is capable of dividing the units into the respective P1 and P2 arrangements may be used.

The units are then delivered to the first and second net tables 80, 100 in the respective P1 and P2 arrangements.

FIGS. 7C and 8C show a further embodiment whereby the flipper 90 of the embodiment of FIGS. 7B and 8B is replaced by a dual flipper 90a,b. Thus, whilst the units may be delivered from the dry block 70 to the idle block 95 via the flipper 90 as a single batch according to the embodiments of 7A, 8A, 7B and 8B, in the embodiment according to FIGS. 7C and 8C, the division of the batch of units occurs on delivery from the dry block 70 to the dual flipper 90A, B.

In the next embodiment shown in FIGS. 7D and 8D, each station within the unit inversion system involves engaging the units in a split batch orientation, being the units are divided into the P1 and P2 arrangements. Thus, the idle block 70A, B receives the units in the P1 and P2 arrangements which are subsequently delivered to the flipper 90A, B and to the dual surfaces of the idle block 95A, B and finally to the first and second net 80, 100.

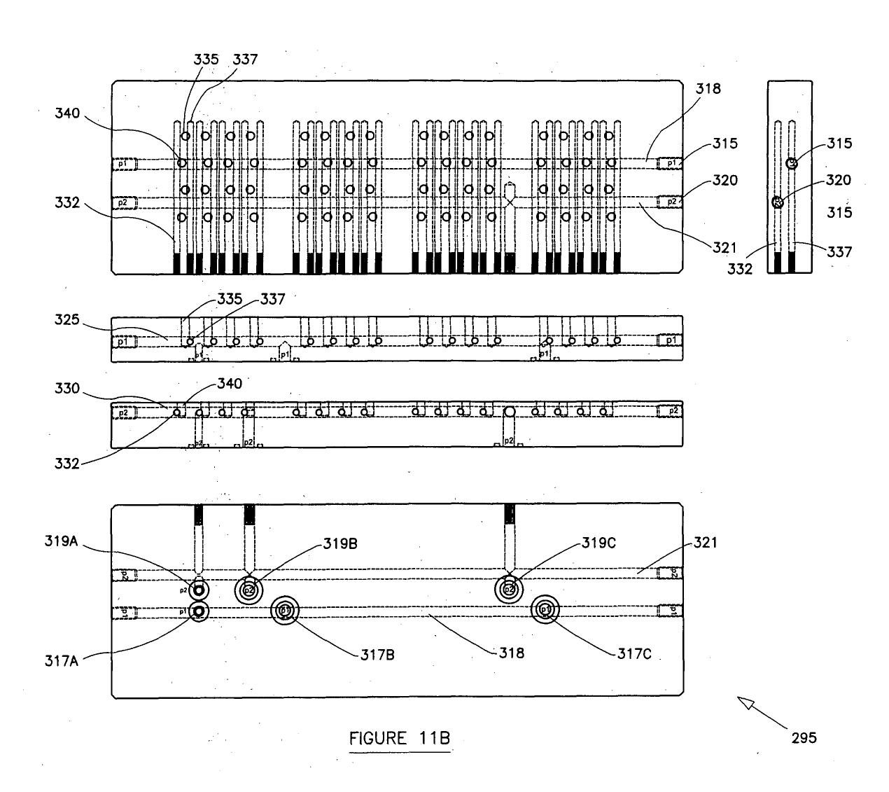

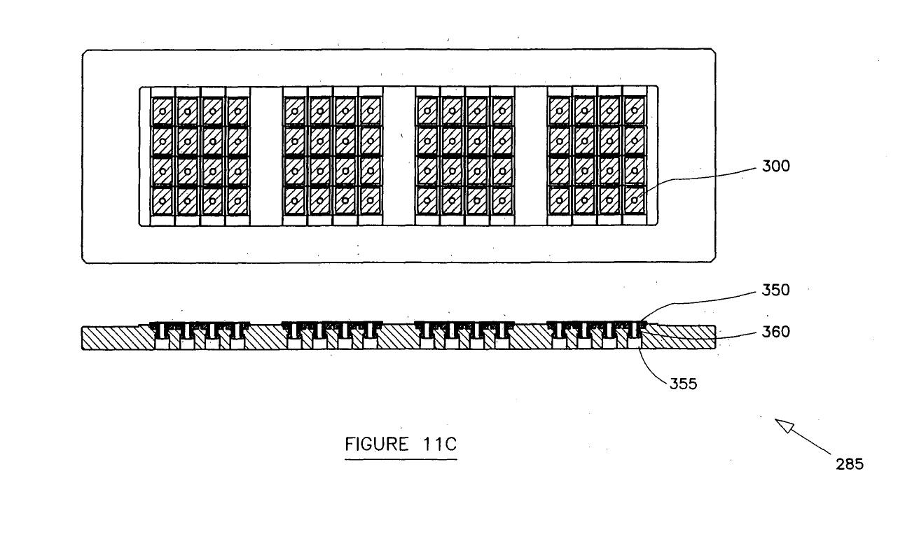

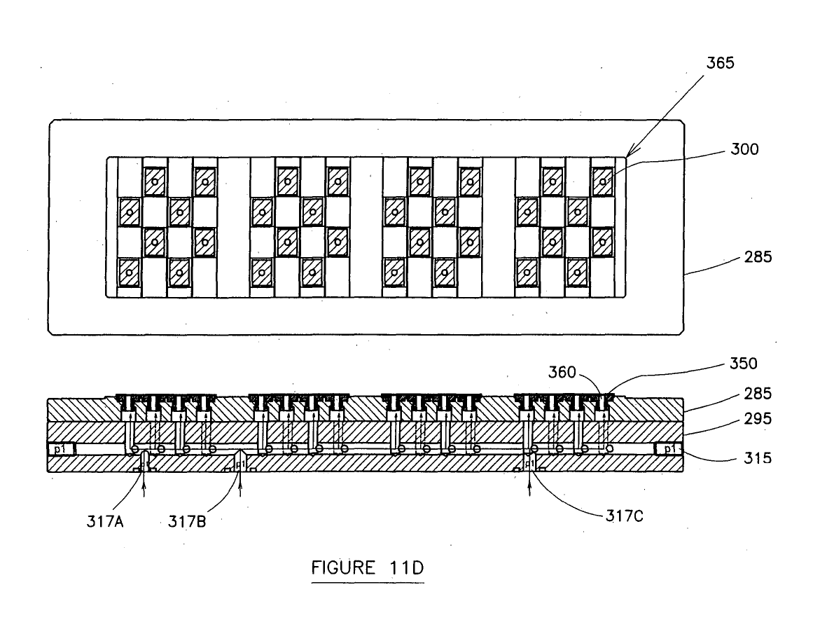

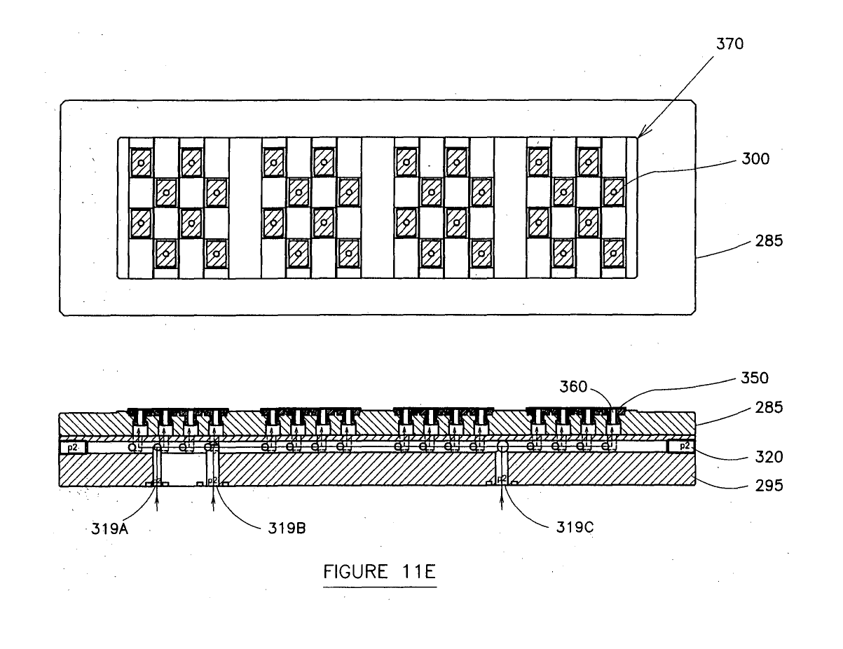

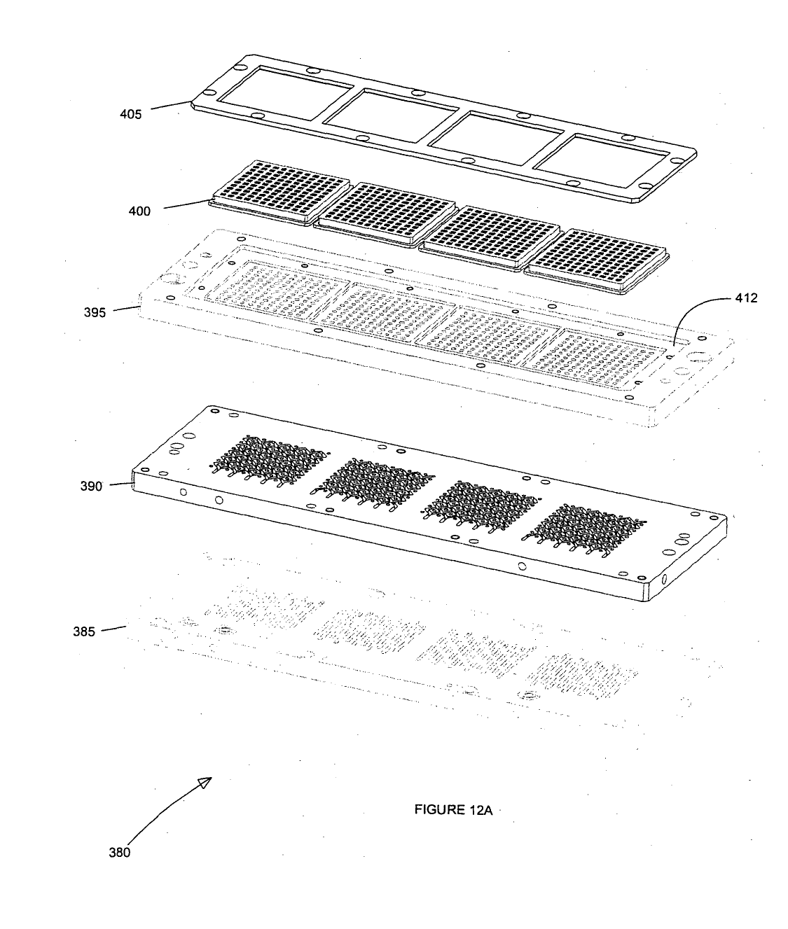

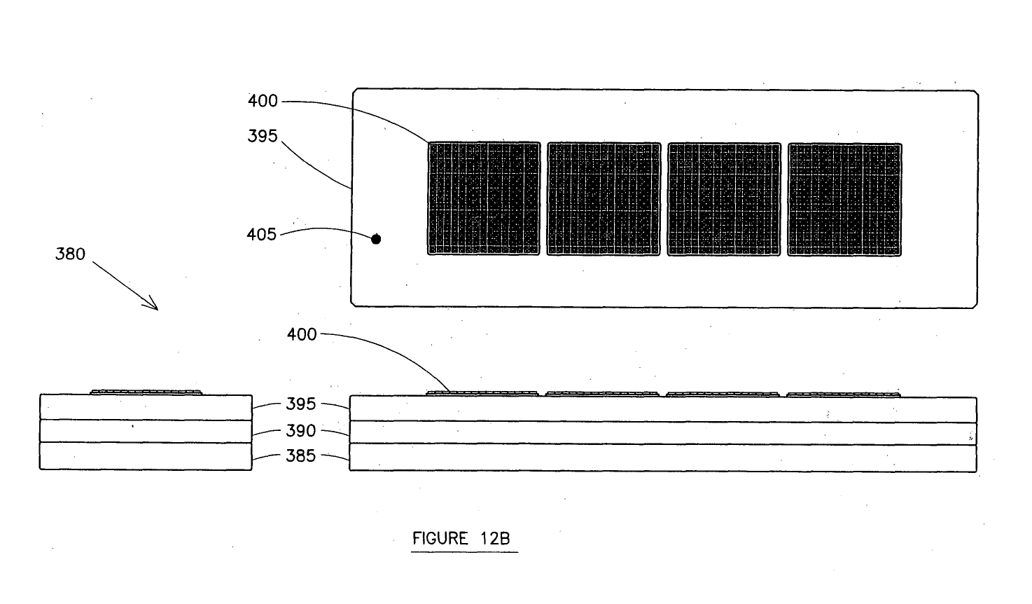

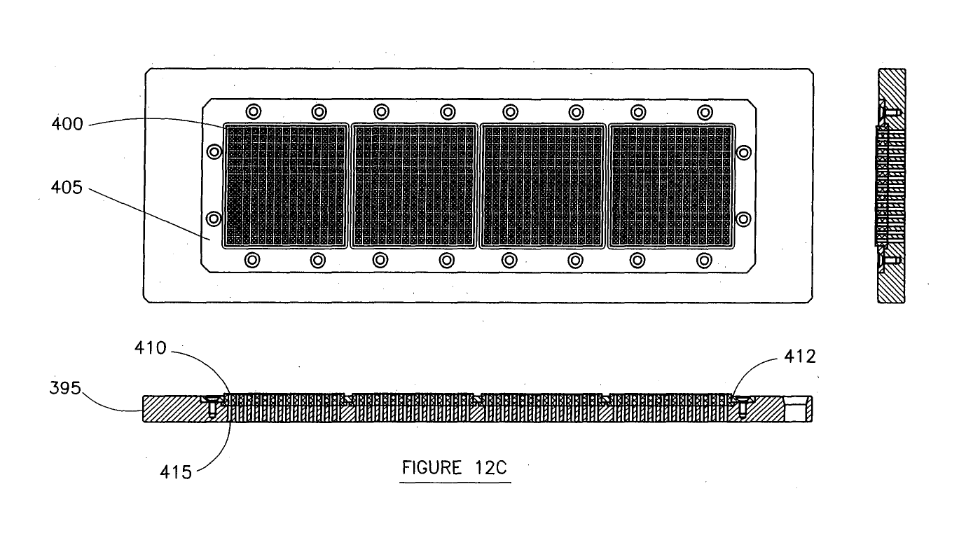

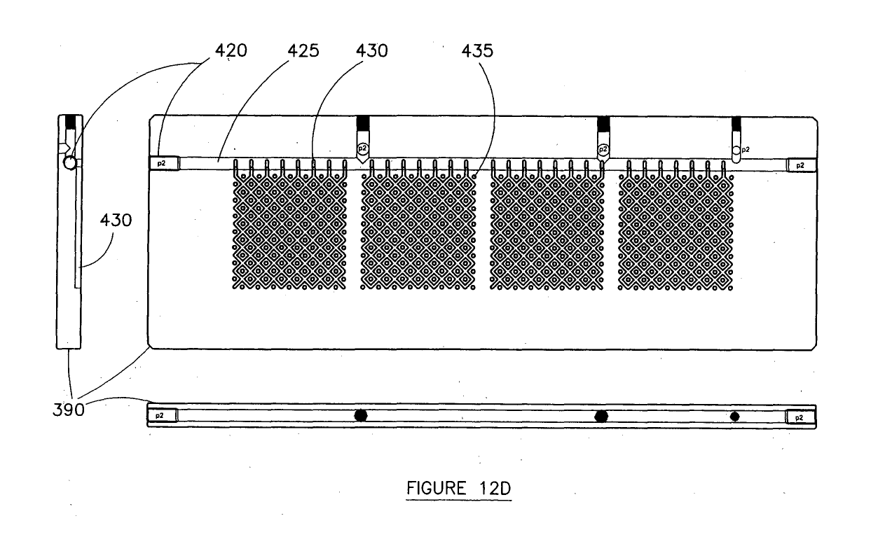

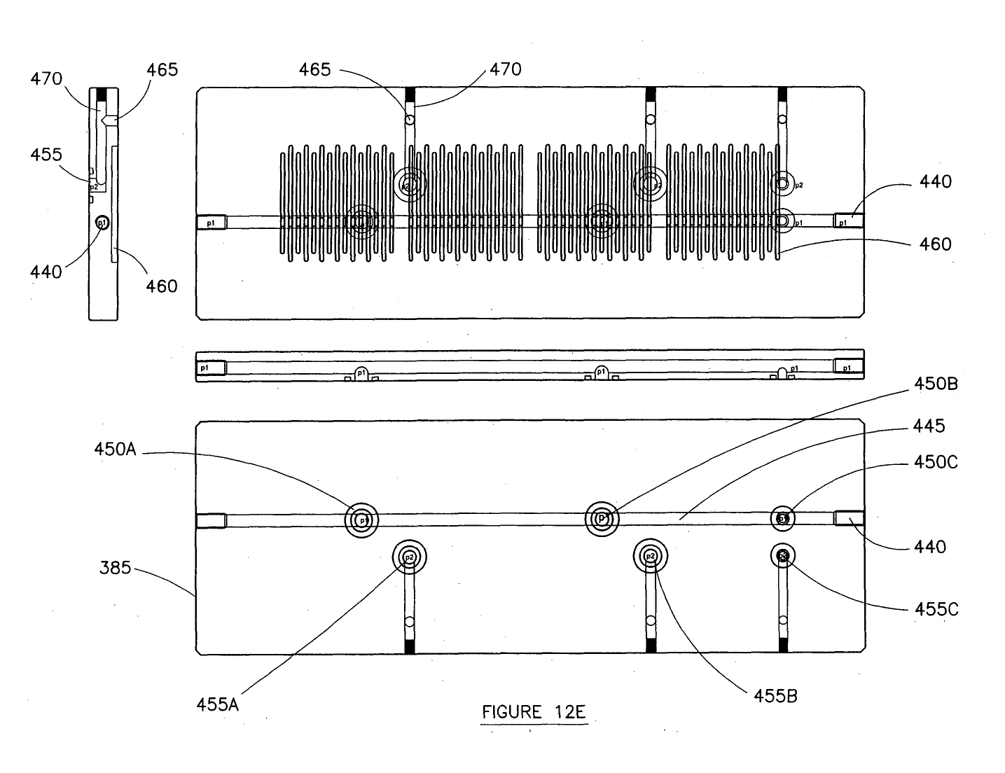

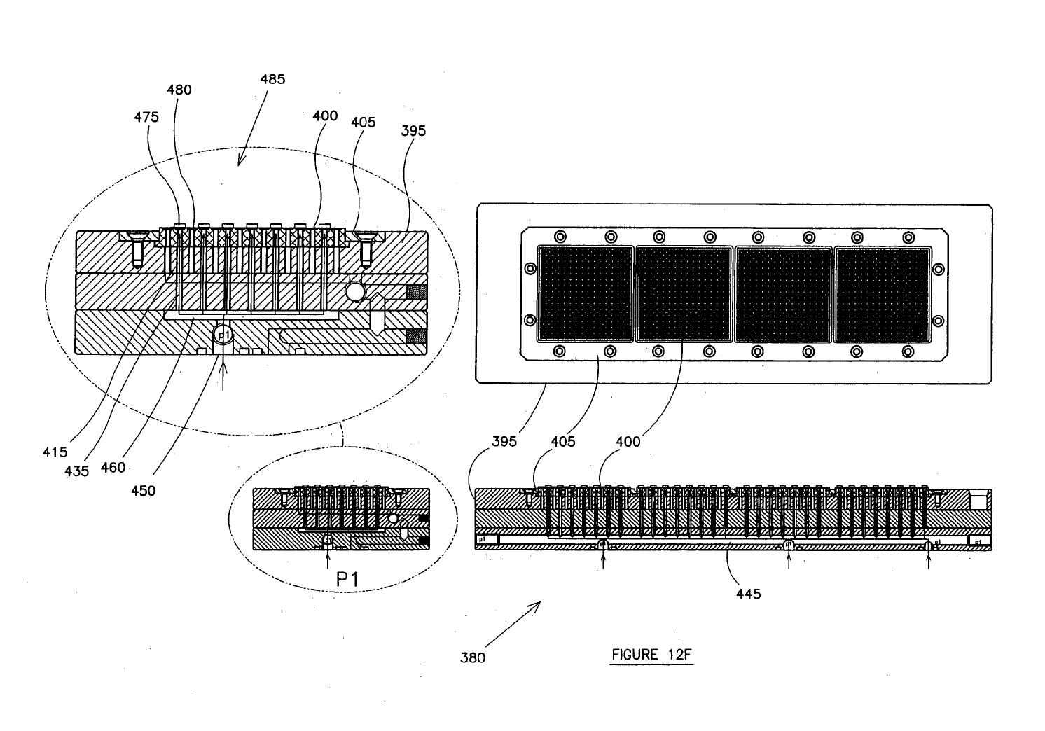

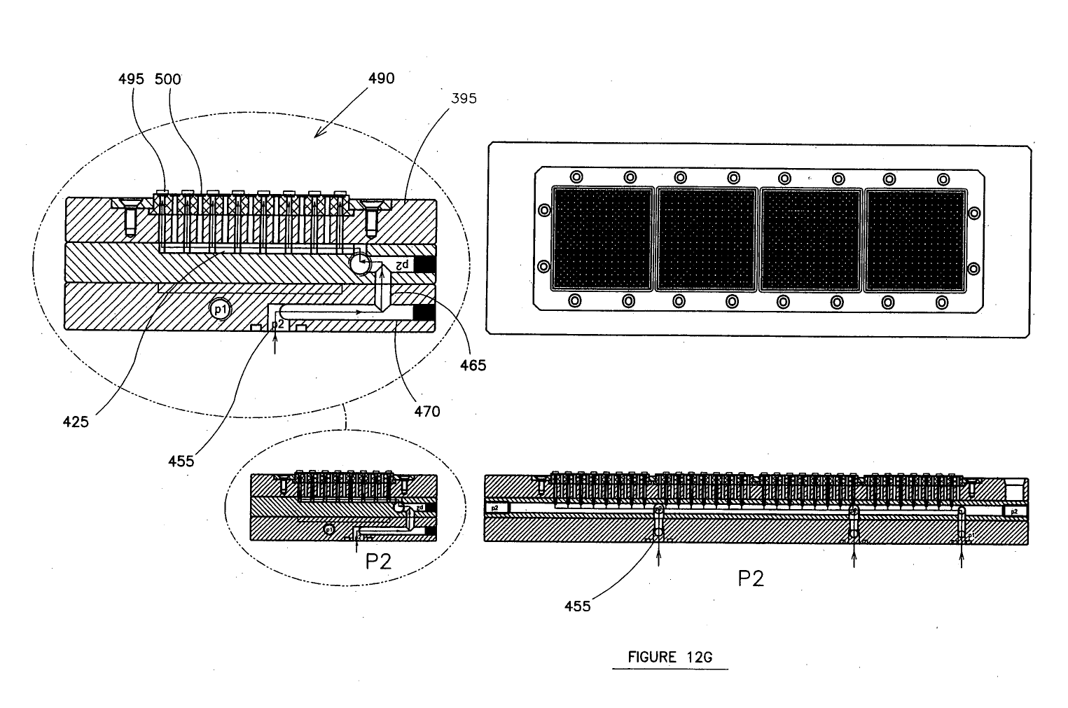

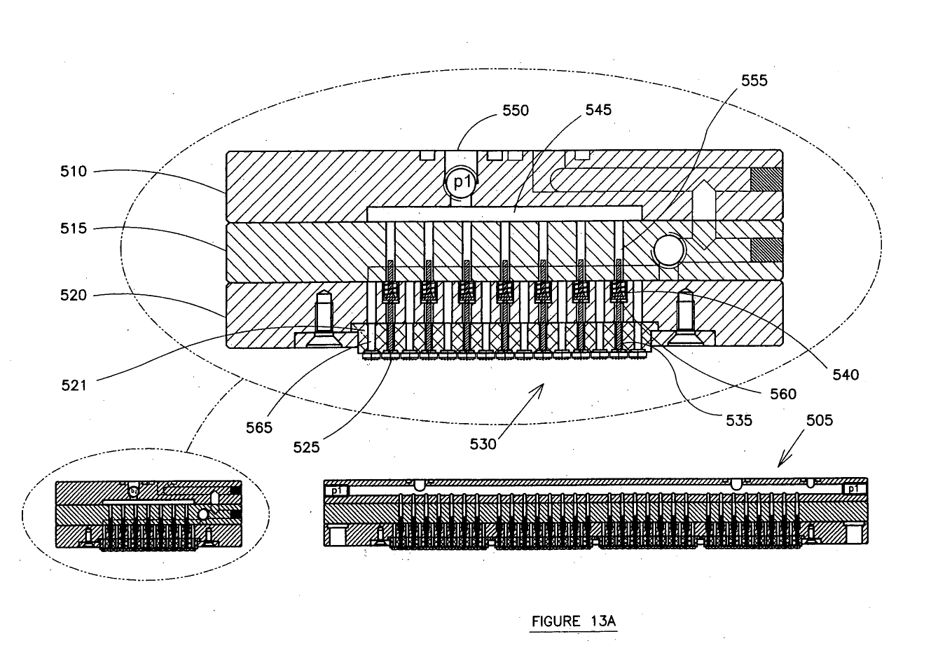

The means by which the units are engaged at the various stations within the inversion system may vary within the scope of the present invention. In a preferred embodiment, a vacuum system will be used to selectively engage and disengage the units according to the stage within the process. Often a conversion kit assembly may be used which may be fitted to a machine and engaged with a vacuum source either within the machine or external to the machine. A conversion kit assembly has the advantage of having a detachable engagement plate to correspond to different types of units being processed by the overall machine and thus is engageable and disengageable within a reasonable turnaround time so as to achieve a high level of flexibility for the machine for as wide as a variety of units as possible. One such conversion kit assembly is that described in PCT/SG2005/000240, the contents of which are incorporated herein by reference. The system was first introduced to the market in November 2004 and is shown in FIGS. 11A to 11E. One embodiment of an invention described herein is shown in FIGS. 12A to 12G. Such a conversion kit assembly may also be used with the inversion system according to the invention described herein.

An exception may be that the dual flipper arrangement shown in FIGS. 7C to 7D may not require this as the inversion process may not require the advantages that such an assembly provides.

The advantages that the division of units into the P1 and P2 arrangements provides vary based upon their respective stations within the inversion system to which the divided arrangement is applied. In general, having the P1 and P2 arrangement provides better clearance for air cleaning so as to remove any detritus deposited from the singulation process. Further, drying of the water cleaned surface will more readily be achieved not to mention any capillary action that may occur through retaining water between adjacent units. In this case, as the clearance between adjacent units after singulation may be of the order of 0.2 to 0.3 mm, a significant quantity of water may be retained. This compares to the clearance provided the P1 and P2 arrangements which will be the width and/or breadth of the unit itself, for instance 1 mm×1 mm. The division of the units into the P1 and P2 arrangement, however, increases the space between units and, therefore, minimizes any further capillary action.

Further still, inspection by imaging devices may be enhanced by providing a greater clearance between units. The straight edges of the units may be more clearly discernible from any detritus that may be left which may be masked by the very small clearance between non-divided arrays of units. Further still, the increase of clearance between the units will allow more light to enter into this space further enhancing the visibility of the units and so consequently the quality of inspection.

A further advantage involves the integrity of the dicing process. Because the original substrate is placed upon a backing such as a plastic sheet, it is possible that the dicing saws may cut through the substrate to singulate the units but fail to completely cut through the plastic backing.

Further, even with the cutting process completed, the cutting debris can be remain in between units because of gap is too small to clean away, particularly if the operator has been using improper cutting blades to produce more debris, or debris which is smaller and so more difficult to remove. Thus, whilst the units have been diced, the overall substrate may not be effectively cut. Such a problem should normally be identified during the inspection, however, given the small clearance between adjacent units, a section that is not completely cut may not be easily identified. If, however, the units are divided into separate orientations, this will only be possible if the plastic backing has been fully cut and so any substrate which is not divisible into the P1 and P2 arrangement will clearly fail inspection and so be more easily identified.

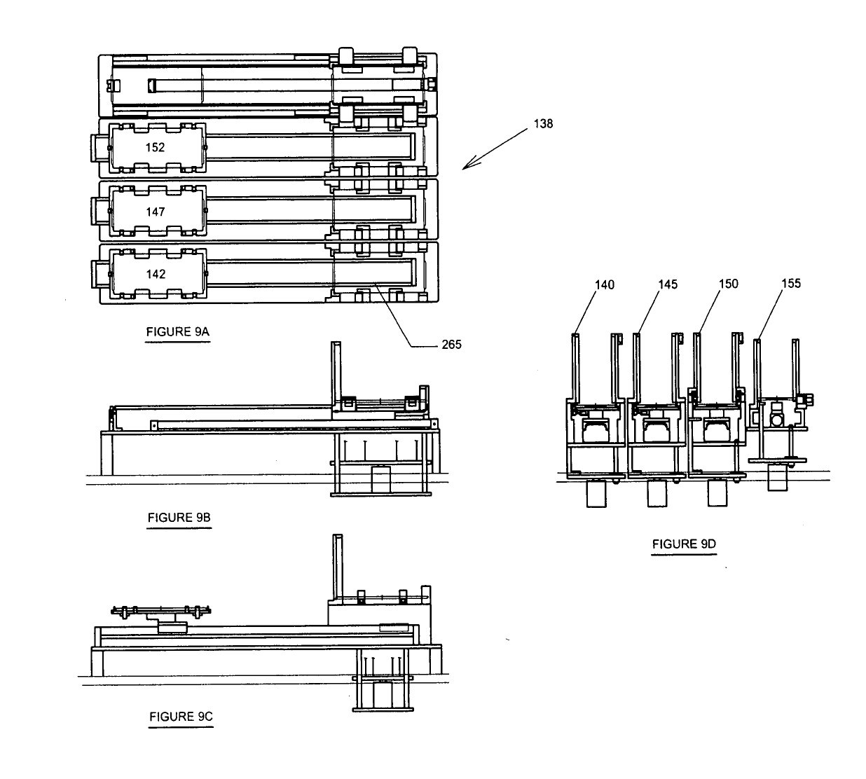

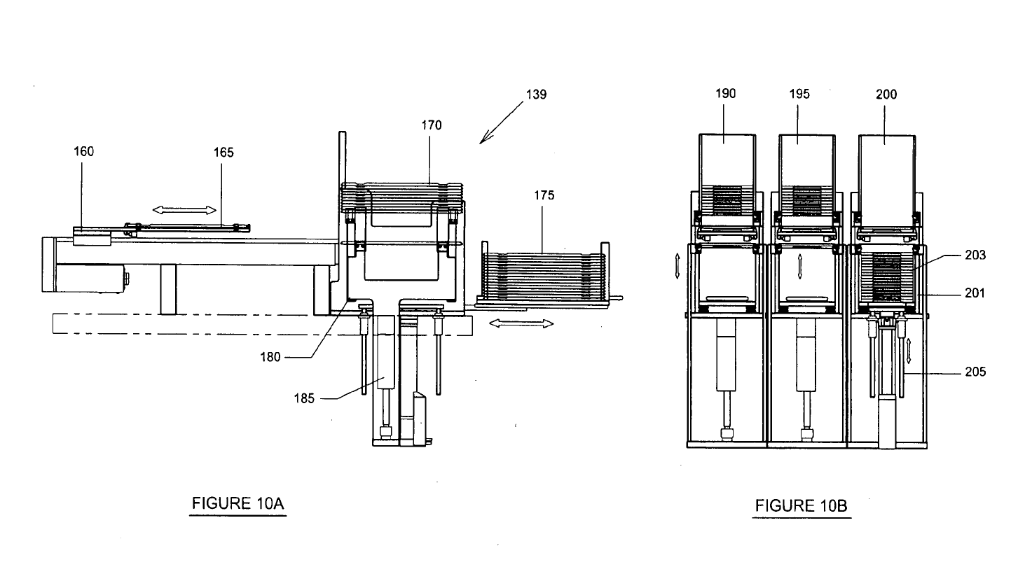

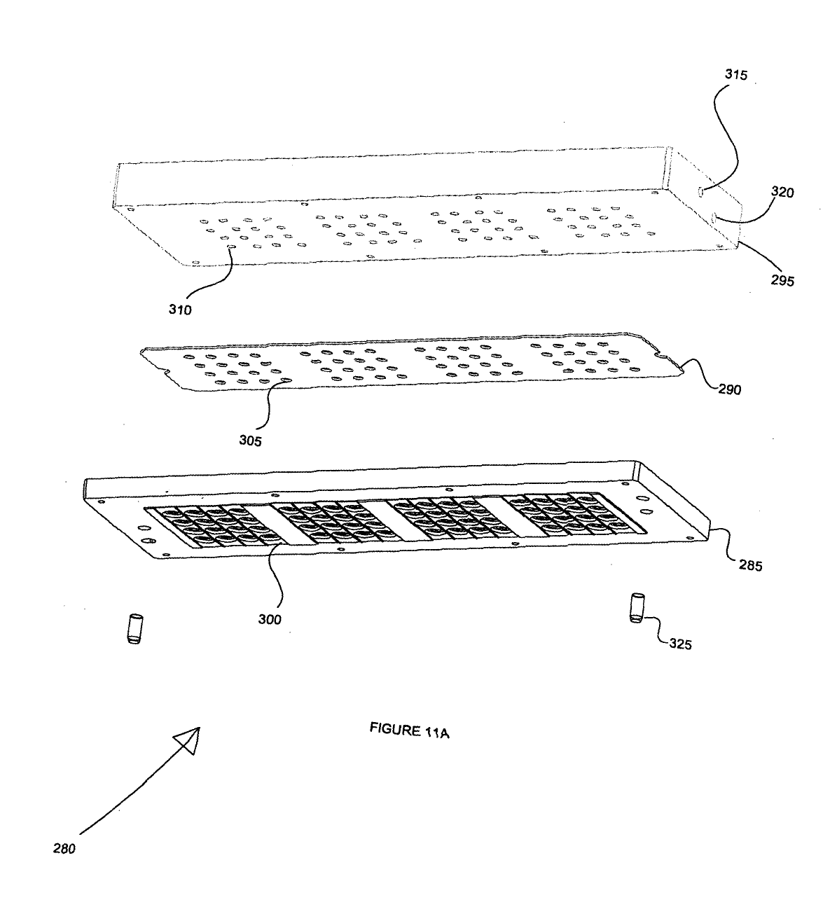

FIGS. 9A to 9D show various views of the unloading assembly 138 incorporating the trays 142, 147, 152 so as to facilitate their deliveries to the corresponding bins 140, 145, 150.

When “good” unit trays 142, 147 and “reworked” unit tray 152 are filled, they are conveyed along a track 265 by a conveyor. The “good” unit trays 142, 147 culminate at ^{“}good” tray assemblies whereupon the trays filled with the “good” units are removed and stacked. Similarly the “reworked” tray 152 is filled and conveyed to a “rework” tray stack assembly whereupon these two are stacked.

FIGS. 10A and 10B show an alternative unloading assembly 139 whereby the various trays are transported upon a plate 165 arranged to travel along the rail to receive the various integrated circuit units not dissimilar from the unloading assembly 138 of FIGS. 9A to 9D. In these alternative arrangements, the trays are stacked 170 on a vertically actuated assembly 180 whereby an actuator 185 moves the stacked trays 203. When the assemblies 190, 195, 200 are full of stacked trays 203, the trays are moved downwards 205 by the actuator 185 and so emptying the assembly 200 whereupon the trays can be removed 175 horizontally through sliding out of the assembly.

FIG. 11A shows a conversion kit assembly 280 according to the prior art. As mentioned, the assembly was first put into practice in November 2004 by the applicant with features associated with the conversion kit assembly 280 relating to PCT/SG2005/000240, the contents of which are incorporated herein by reference. The assembly 280 comprises an engagement plate 285 and a manifold plate 295 with a gasket plate 290 fitting between the engagement plate 285 and manifold plate 295. The assembly 280 is held together by a plurality of fasteners such as location pin 325. FIGS. 11B to 11E show the various features of the assembly 280.

The manifold plate 295 is used to engage a vacuum source (not shown) within an existing machine with ports in the manifold plate to engage two separate vacuum sources designated P1 and P2. The intention is to provide a different vacuum attachment for diced integrated circuit units so that the units can be selectively held in a chequer board arrangement such as the P1 chequer board arrangement shown in FIG. 11D or the P2 chequer board arrangement shown in FIG. 11B. The manifold plate can also be used to simultaneously engage all ports so that both the P1 and P2 arrangements can be used by providing a vacuum source to each unit and thus maximizing the capacity of the engagement 285.

Turning to FIG. 11B, there is shown on an underside of the manifold plate 295, a series of P1 ports 317A-C and P2 ports 319A-C. These may correspond to two different locations of vacuum sources so as to increase the adaptability of the assembly 280 to a variety of different machines. Further, side ports are also provided 315, 320 in case the machines to be used have the vacuum source located in a different position. In this case, said ports may also be machining holes to facilitate manufacturing of the manifold.

Nevertheless, all of the P1 ports 317A-C, 315 are in communication with a collection of ducts which correspond to only half of the array of engagement portions 300 located in the engagement plate 285. These portions relate to the P1 arrangement shown in FIG. 11D.

Correspondingly, the P2 arrangement ports 319A-C, 320 are in communication with a different arrangement of ducts which are in further communication with the remaining half of portions for engaging units in a similar but opposing chequer board pattern as shown in FIG. 11E. It follows that the P1 arrangement of ducts is isolated from the P2 arrangement of ducts and, therefore, to engage units in all portions of the engagement plate 285, at least one P1 and at least P2 port must be engaged so as to feed the vacuum source to the respective portions within the engagement plate.

With reference to the P1 arrangement of ducts, each of the ports 317A-C, 315 feed directly to the P1 longitudinal duct 318. Feeding from the longitudinal duct 318 are a plurality of orthogonally disposed ducts 337 which in turn feed to vertical ducts 335. The vertical ducts 335 then correspond to ducts within the engagement plate 285 for subsequent engagement with an integrated circuit within the corresponding portion.

Similarly the P2 duct arrangement includes engaging a vacuum source at P2 ports 319A-C, 320. These ports are in communication with a further longitudinal duct 321. As with the longitudinal duct 318, the P2 longitudinal duct 321 runs the full length of the manifold plate 295 and includes ports at either end of said duct. Thus, the ports 319A-C access the longitudinal duct 321 from the base of the manifold plate 295 with the two remaining ports 320 located at opposed ends of said plate 295.

The longitudinal duct 321 is in communication with a plurality of orthogonally ducts 332 which further have a plurality of vertical ducts 340 projecting upwards to the upper surface of the manifold plate 295. It is at that upper surface that the vertical ducts 340 correspond to ducts in the engagement plate 285 for providing a vacuum to the various engagement portions 300.

FIG. 11C shows the engagement plate 285. Fitted to the engagement plates 285 are inserts 350 which form a rubber mount to receive the integrated circuit units. Accordingly, the engagement portion 300 includes the vertical duct 355 and the insert 350 which together receive the unit. The unit itself is located on an upper surface of the insert 350 and is held in place through a vacuum provided through a duct 360 within the insert which is in communication with the vertical duct 355 of the engagement plate 285. In this instance, the embodiment shown in FIG. 11C shows the engagement plate 285 having inserts 350 located to receive a full capacity of units. As will be shown in FIGS. 11D and 11E, the inserts 350 can be removed so that they form a chequer board arrangement and so operate at half capacity to receive the integrated unit.

FIG. 11D shows the P1 arrangement 365 formed by the inserts 350 within the engagement portions 300. The engagement plate 285 has also been mounted to the manifold plate 295. Further it can be seen that the flow path for the vacuum source begins at the ports 317A-C on the base of the manifold 295 received the vacuum which travels through the longitudinal and octagonal ducts and eventually through the vertical ducts to the vertical ducts of the engagement plate. The vacuum then communicates with units mounted to the rubber inserts 350 through ducts 360 within the inserts 350. Thus the flow path for the vacuum using the P1 arrangement provides a vacuum source to the units specifically within the P1 arrangement 365.

FIG. 11E shows a similar situation for the P2 arrangement. The upper surface of the engagement plate 285 has a P2 arrangement 370 of the inserts 350 which is opposed to that of the P1 arrangement shown in FIG. 11D.

In this case, a vacuum is provided to the inserts 350 through the P2 ports 319A-C in the base of the manifold plate 295. Passing through the longitudinal and vertical ducts these then align with the vertical ducts in the engagement plate 285 corresponding to the P2 arrangement 370. Accordingly, in order to engage units in a P2 arrangement 370, a vacuum source is applied to the P2 ports.

FIG. 12A shows a conversion kit assembly kit 380 according to one embodiment of the present invention. Here the assembly 380 includes a P1 manifold plate 385 and a separate and distinct P2 manifold plate 390. The manifold plates are engaged with an engagement plate 395 which includes a plurality of modular engagement members 400 which fit within a recess of the engagement plate 395 and held in place by clamping plate 405.

The conversion kit assembly according to the present invention provides distinct manifold plates as compared to that of the prior art which has a single manifold plate with the respective duct arrangement for each orientation within the same plate. By providing distinct manifold plates, this allows greater modularity, including different plates having different duct arrangements to meet the requirements of the specified units being used.

In one batch, two manifold plates may be arranged to engage an array numbering, say 11×11 units, each unit being of size 1 mm×1 mm. However, the next arrangement might be 5×5 using 3 mm×3 mm units. To provide the desired arrangement of units in a chequer board or any other pattern, the modular manifold plates may be changed accordingly to fit the desired pattern. This also provides for an arrangement where a chequer board pattern is not desired but entire strips of units may wish to be held in place.

FIG. 12C shows a detailed view of the engagement plate 395 having the modular panels 410 placed within the recess 412 within the engagement plate 395. Further the clamping plate 405 is mounted to the engagement plate 395 and so holding the modular panels 410 in place.

It will be noted that the engagement plate includes a plurality of vertical ducts 415 corresponding to each possible location of a unit to be engaged by the panels 410. Thus, the ducts 415 correspond to other ducts within the panels 410 to allow communication with the vacuum source so as to hold the units in place whilst mounted to the conversion kit assembly 380.

FIG. 12D shows the P2 manifold plate 390. Here P2 ports 420 are located at opposed ends of the plate 390 and communicate with a longitudinal duct 425. From the longitudinal duct 425 extends an arrangement of ducts 430 positioned to correspond to the P2 arrangement intended for use with the engagement plate 395. In this embodiment, the P2 duct arrangement involves a grid pattern formed as channels within the top surface of the plate 390. Thus in a further departure from the prior art rather than ducts being drilled into the manifold plate, in this embodiment the duct arrangement is provided by open grooves in the top surface which on engagement with the engagement plate 395 are sealed and so effectively act as closed ducts in the same way that the drilled ducts of the prior art are used. Apart from ease of manufacturing, this also allows for a thinner plate to be used, as there is no need for a minimum thickness of plate in order to drill a hole in the plate.

Within each square of the grid formed by the P2 duct arrangement 430 are vertical ducts 435 which pass through the thickness of the P2 manifold plate 390 so as to be in communication with the underlying P1 manifold plate 385. Therefore, with the P2 manifold plate 390 providing communication with the vacuum source to the engagement plate 395, the vertical ducts 435 passing through the P2 manifold plate 390 permit bypassing of the P2 manifold plate 390 by the vacuum source having a P1 arrangement.

FIG. 12E shows the P1 manifold plate 385. In the base of the P1 manifold plate 385 are P1 ports 450A-C and P2 ports 455A-C. The ports associated with the P2 arrangement communicate with vertical ducts passing through the P1 manifold plate and so bypassing the P1 arrangement of ducts.

The P1 ports 450A-C communicate with a longitudinal duct 445 running the full length of the plate 385 and having P1 ports 440 at either end so as to provide connection with a vacuum source from the side portion of the plate.

The longitudinal duct 445 communicates with a plurality of orthogonal ducts 460. In this case the orthogonal ducts are a plurality of parallel grooves in the top face of the P1 manifold plate 385 and are positioned so as to correspond with the vertical ducts 435 in the P2 manifold plate 390. Thus the vacuum source corresponding to the P1 arrangement passes through the ports 450A-C, 440 through the orthogonal ducts/grooves 460 and through the vertical ducts 435 to then communicate with the engagement plate 395.

FIG. 12F shows the conversion kit assembly 380 and in particular highlighting the vacuum path for the P1 arrangement 485. P1 port 450 engages with a vacuum source (not shown). The vacuum communicates with a longitudinal duct 445 which in turn communicates with octagonal duct 460. The octagonal duct 460 located in the top surface of the P1 manifold plate 385 corresponds with vertical ducts 435 passing through the P2 manifold plate 390. In the engagement plate 395 are a plurality of vertical ducts 415 with certain of these but not all corresponding in position with the vertical ducts 435 of the P2 manifold plate 390.

Mounted to the panel 400 are integrated circuit units 475 corresponding to the P1 arrangement 485. The engagement portions 480 corresponding to the P2 arrangement are consequently vacant and so providing sufficient clearance between the integrated circuit units 475 to benefit from advantages such as inspection, cleaning and access.

FIG. 12G shows the alternative arrangement for the P2 arrangement 490 of the units. Here, the P2 ports 455 bypass the P1 manifold plate 385 through ducts 465, 470. The vertical duct 465 corresponds to the duct arrangement in the P2 manifold plate 390 to feed the vacuum to a longitudinal duct 425 which subsequently feeds to the horizontal ducts 430. These then correspond to the vertical ducts through the engagement plate 395 and finally to the corresponding vertical ducts in the panel 400 which are specific to the P2 arrangement 490. Thus, the engagement of units 495 in a P2 arrangement is facilitated leaving the voids 500 for the intermediate portions.

FIGS. 13A and 13B show the vacuum engaged and vacuum disengaged states of a picker for engaging units from above and moving these to the corresponding location. The picker operates on a vacuum engaged system whereby spring loaded engagement fingers 530 operate under a vacuum system. The picker includes an assembly 505 comprising a picker manifold plate 510 for engaging a port 550 with a vacuum source (not shown). The port is in communication with a horizontal arrangement of ducts 545 which provide a vacuum with vertical ducts 555 with each duct corresponding to a selected engagement finger 530. As with the conversion kit assembly 380 described in FIGS. 12A to 12G, the picker assembly 505 operates with either a P1 or P2 arrangement and, therefore, the picker assembly 505 further includes an engagement plate 520 having engagement fingers 530 in alternating ducts so as to engage units laid out in a chequer board arrangement.

FIG. 13A shows the engagement fingers 530 in the retracted position corresponding to the activation of the vacuum source. In this position, a sealing flange 560 is drawn into the block by the vacuum and, therefore, bringing the engagement finger 530 into engagement with the panel 521. The application of the vacuum draws the sealing flange 560 into the engagement block 520, retracting the engagement finger 530, which consequently compresses a spring 540.

FIG. 13B shows the result of the release of the vacuum, which releases the force on the sealing flange 560. The spring is released, pushing the engagement finger 530 so as to project from the panel 521 and consequently having engagement surfaces 525 projecting away from the panel and so permitting access to engage units.

On contacting the units with the contact surface 525, the vacuum can then be reactivated having the dual effect of engaging the units on to the contact surface 525 and automatically drawing the sealing flange 560 back within the engagement block 520.

1. An assembly for cutting a plurality of substrates into individual integrated circuit units comprising
a first block for receiving a first substrate, said first block movable between a first loading position, a first alignment inspection station and a first cutting zone;
a second block for receiving a second substrate, said second block movable between a second loading position, a second alignment inspection station and a second cutting zone;
a cutting device for cutting a substrate into individual integrated circuit units, said cutting device movable between the first cutting zone and the second cutting zone, and;
an alignment inspection device for determining the alignment of a substrate positioned on either the first or second block, said alignment inspection device movable between the first alignment inspection station and the second alignment inspection station.

2. The assembly according to claim 1 further comprising a cleaning station for cleaning a surface of the first or second substrate exposed during cutting wherein said first and second blocks are movable to said cleaning station.

3. The assembly according to claim 2 wherein said cleaning station includes a first cleaning portion for cleaning said first substrate whilst the first block is within the cleaning station and a second cleaning portion for cleaning said second substrate when the second block is in the cleaning station.

4. The assembly according to claim 2 wherein said cleaning station includes a cleaning device movable between a first cleaning zone and a second cleaning zone, said first
and second cleaning zones located within the cleaning station; said first block movable to the first cleaning zone and the second block movable to the second cleaning zone.

5. The assembly according to claim 1, further including a loading device for loading substrates to the first and second blocks in an alternating sequence.

6. The assembly according to claim 5, wherein the loading device includes a loading assembly for loading individual substrates to a table and a frame picker for engaging and moving the substrates from the table to the respective blocks.

7. The assembly according to claim 1, further including a bulk unit picker for collectively engaging and removing the individual units from said blocks.

8. The assembly according to claim 7 further including a tertiary cleaning device arranged to clean the individual units whilst said units are engaged with the bulk unit picker.

9. The assembly according to claim 7, further including a sorting system for receiving integrated circuit units from the bulk unit picker and sorting said units into predetermined categories.

10. The assembly according to claim 9 wherein the sorting system includes
a dry block for receiving the units from the bulk unit picker;
a first net table for receiving a first batch of said units, said first net table movable between a first receiving position and a first sorting position;
a second net table for receiving a second batch of units, said second net table movable between a second receiving position and a second sorting position, and;
a second bulk unit picker for delivering said respective first and second batch of units from the dry block an idle block, and subsequently from the idle block to the first and second net tables whilst in respective first and second receiving positions.

11. The assembly according to claim 10 wherein the dry block includes a first and second surface, said bulk unit picker arranged to deliver the first batch of units to the first dry block surface and the second batch of units delivered to the second dry block surface, said batches placed in a chequer board arrangement on said first and second dry block surfaces.

12. The assembly according to claim 10, wherein the idle block includes a first and second surface, said second bulk unit picker arranged to deliver the first batch of units to the first idle block surface and the second batch of units delivered to the second idle block surface, said batches placed in a chequer board arrangement on said first and second idle block surfaces.

13. The assembly according to claim 10 wherein the sorting system further includes a first and second discreet unit delivery system for delivering said units from respective first and second net tables into designated categories whilst said first and second net tables are in respective first and second sorting positions.

14. The assembly according to claim 10, wherein said discreet unit delivery system includes a plurality of discreet unit pickers movable along linear rails between the respective sorting positions and an unloading assembly.

15. The assembly according to claim 11 wherein the unloading assembly includes trays for receiving units corresponding to categories, said trays movable along linear rails for receiving said units and delivering said units to bins corresponding to said categories.

16. The assembly according to claim 12 wherein said categories include: “good” for undamaged units, “rework” that may be elevated to “good” category on further processing and “reject” for units that are to be disposed.

17. The assembly according to claim 7, further including a flipper for receiving said units from said unit picker, said flipper arranged to invert the units prior to delivery to said respective net tables.

18. A method for cutting a plurality of substrates into individual integrated circuit units, the method comprising the steps of:
placing a first substrate on a first block;
moving said first block between a first loading position, a first alignment inspection station and a first cutting zone;
placing a second substrate on a second block;
moving said second block between a second loading position, a second alignment inspection station and a second cutting zone;
moving a cutting device between the first cutting zone and the second cutting zone for cutting a substrate, and cutting the first or second substrate into integrated circuit units when located in said zone;
respective first or second moving an alignment inspection device between the first alignment inspection station and the second alignment inspection station and determining the alignment of the first or second substrate when located in said respective alignment station.

19. The method according to claim 18 further including the steps of:
moving said first block to a cleaning station;
cleaning a surface of said first integrated circuit units exposed during cutting.

20. The method according to claim 17, further including the steps of moving said second block to a cleaning station and cleaning a surface of said second integrated circuit units exposed during cutting.

21. The method according to claim 18, further including the steps of removing the units from said first block using a bulk net picker and returning said first block to the cleaning station for cleaning the first block.

22. The method according to claim 18, further including the steps of removing said second integrated circuit units from the second block using the bulk net picker and returning said second block to the cleaning station for cleaning said second block.

23. An assembly for cutting a plurality of substrates into individual integrated circuit units comprising
a first block for receiving a first substrate, said first block movable between a first loading position and a first cutting zone;
a second block for receiving a second substrate, said second block movable between a second loading position and a second cutting zone;
a cutting device for cutting a substrate into individual integrated circuit units, said cutting device movable between the first cutting zone and the second cutting zone.

24. A method for cutting a plurality of substrates into individual integrated circuit units, the method comprising the steps of:
placing a first substrate on a first block;
moving said first block between a first loading position and a first cutting zone;
placing a second substrate on a second block;
moving said second block between a second loading position and a second cutting zone;
moving a cutting device between the first cutting zone and the second cutting zone for cutting a substrate, and cutting the first or second substrate into individual integrated circuit units when located in said zone.

25. A sorting system for sorting integrated circuit units comprising
a dry block for receiving the units from a bulk unit picker;
a first net table for receiving a first batch of said units, said first net table movable between a first receiving position and a first sorting position;
a second net table for receiving a second batch of units, said second net table movable between a second receiving position and a second sorting position, and;
a second bulk unit picker for delivering said respective first and second batch of units from the dry block an idle block, and subsequently from the idle block to the first and second net tables whilst in respective first and second receiving positions.

26. A unit inversion system comprising
a dry block for receiving a plurality of units
a flipper for receiving the plurality of units from the dry block and inverting said units
a net table for receiving the units from the flipper
wherein said net table includes two surfaces, the surfaces arranged to receive respective first and second batches of units in a predetermined orientation.

27. The unit inversion system according to claim 26 further including a picker for moving said units from the dry block to the flipper and from the flipper to the net table.

28. The unit inversion system according to claim 26, wherein said flipper includes two surfaces, the surfaces arranged to receive the respective first and second batches of units in the predetermined orientation.

29. The unit inversion system according to claim 26, wherein the dry block includes two surfaces, the surfaces arranged to receive the respective first and second batches of units in the predetermined orientation.

30. The unit inversion system according to claim 26, further including an idle block, said plurality of units delivered to the idle block prior to delivery to the net table.

31. The unit inversion system according to claim 30 wherein the idle block includes two surfaces, the surfaces arranged to receive the respective first and second batches of units in the predetermined orientation.

32. The unit inversion system according to claim 27, wherein the picker is arranged to engage selected units from the plurality of units and place said selected unit in the first or second predetermined arrangement.

33. The unit inversion system according to claim 26, wherein the units are engaged on respective engagement services using a selectively operable vacuum.

34. The unit inversion system according to claim 26, wherein said predetermined orientation includes a chequer board arrangement such that the chequer board arrangement of the first batch of units is an opposed orientation to the chequer board arrangement of the second batch of units.

35. A conversion kit assembly for receiving integrated circuit units comprising:
an engagement member, having engagement portions in an engagement face of said engagement member, each portion arranged to receive a single unit;
a first manifold element having a first duct network, said first manifold element engageable with a first vacuum source;
a second manifold element having a second duct network, said second manifold element engageable with a second vacuum source;
wherein on assembling the engagement member, the first manifold element and the second manifold element, said first vacuum source is in vacuum communication with a first plurality of engagement portions and the second vacuum source is in communication with a second plurality of engagement portions, the first and second plurality of engagement portions forming respective pre-determined arrangement.

36. The conversion kit assembly according to claim 35, wherein the engagement member includes an assembly including an engagement plate for mounting to the first manifold element and a separable engagement panel, coupled to the engagement plate, said engagement panel including the engagement face.

37. The conversion kit assembly according to claim 35, wherein at least of said manifold elements includes a unitary plate into which the duct system has been machined.

38. The conversion kit assembly according to claim 37, wherein the machined duct system includes any one or a combination of drilled, milled or routed into said plate.

39. The conversion kit assembly according to claim 36, wherein in the assembled form the engagement member and manifold elements form layers, said layers coupled using fasteners.

40. The conversion kit assembly according to claim 36, wherein said manifold elements are coupled side by side to form a manifold block, said block coupled to a second face, opposed to the engagement face, of the engagement member.

41. A picker assembly for engaging integrated circuit units comprising, an engagement member, having a plurality of engagement fingers projecting from an engagement face of said engagement member, each engagement fingers arranged to engage a single unit;
said engagement fingers arranged to extend away from the engagement face on activation of a vacuum source applied to said engagement finger and retract on deactivation of said vacuum source;
a first manifold element having a first duct network, said first manifold element engageable with a first vacuum source;
a second manifold element having a second duct network, said second manifold element engageable with a second vacuum source;
wherein on assembling the engagement member, the first manifold element and the second manifold element, said first vacuum source is in vacuum communication with a first plurality of engagement fingers and the second vacuum source is in communication with a second plurality of engagement fingers, the first and second plurality of engagement fingers forming respective pre-determined arrangement.

42. The picker assembly according to claim 40, wherein said engagement finger includes a shaft located in a duct of said engagement member, an engagement surface projecting from the engagement face at a first end of said shaft, a spring mounted co-linearly with said shaft and a sealing flange integral with said shaft, the spring is mounted between the sealing flange and an abutment portion of said picker assembly such that on activation of the vacuum source, the sealing flange is biased toward said vacuum source, and consequently compressing said spring, and on release of said vacuum source, said spring biases the sealing flange back to an extended position.

43. The unit inversion system according to claim 26, wherein a surface of any one or a combination of the idle block, dry block, net table and flipper includes a conversion kit assembly.

44. The unit inversion assembly according to claim 26, wherein the picker includes a picker assembly.
